(19) United States
(12) Patent Application Publication
(10) Pub. No.: US 2026/0324379 A1
(43) Pub. Date: Oct. 15, 2026

(54) CONDUCTIVE LINER FOR RUTHENIUM SEMI-DAMASCENE SUBTRACTIVE INTERCONNECT AND METHODS OF MAKING THE SAME

(71) Applicant: Tokyo Electron Limited, Tokyo (JP)

(72) Inventors: Hirokazu Aizawa, Albany, NY (US); Kai-Hung Yu, Albany, NY (US); Yuji Otsuki, Albany, NY (US); Joshua Mayersky, Albany, NY (US); Takumi Nishinobo, Albany, NY (US)

(21) Appl. No.: 19/175,894

(22) Filed: Apr. 10, 2025

(51) Int. Cl. H01L 21/768; H01L 21/3205; H01L 21/3213; H01L 23/528; H01L 23/532

(52) U.S. Cl. CPC H10W 20/056; H10P 14/412; H10P 50/71; H10W 20/034; H10W 20/092; H10W 20/425; H10W 20/427

(57) ABSTRACT

A method for making a semiconductor device can include providing a low-k dielectric layer having a via hole formed therein, wherein the via hole opens to an underlying conductive structure, forming a conductive liner with a line liner portion directly on a top surface of the dielectric layer and a via sidewall liner portion directly on a sidewall of the via hole, and forming a ruthenium interconnect structure directly on the conductive liner using a subtractive interconnect formation process so that a via plug portion is contiguous and integral with a line portion, the line portion is electrical connected with the underlying conductive structure via the via plug portion, the via sidewall liner portion is between the via plug portion and the sidewall of the via hole, and the line liner portion is between the line portion and the top surface of the dielectric layer.

### TECHNICAL FIELD

The present disclosure relates generally to methods for manufacturing semiconductor devices, and more particularly, providing a conductive liner for a ruthenium semi-damascene subtractive interconnect for a method for manufacturing semiconductor devices.

### BACKGROUND

An integrated circuit contains various semiconductor devices and a plurality of conducting metal paths that provide electrical power to the semiconductor devices and allow the semiconductor devices to share and exchange information. Within the integrated circuit, metal layers are stacked on top of one another using intermetal and interlayer dielectric layers (ILDs) that insulate the metal layers from each other. The manufacturing stage and device portion for such intermetal and interlayer dielectric layers, or interconnects, is typically referred to as back-end-of-the-line (BEOL).

Normally, each metal layer must form an electrical contact to at least one additional metal layer. Such electrical contact can be achieved by etching a feature (i.e., a via) in the interlayer dielectric layer that separates the metal layers, and filling the resulting via with a metal to create an interconnect. A “via” sometimes refers to any feature such as a hole, line, or other similar feature formed within a dielectric layer and filled with a metal structure that provides an electrical connection or metal interconnect through the dielectric layer to another conductive structure underlying the dielectric layer. Similarly, metal structures connecting two or more vias are sometimes referred to as “trenches” or metal lines or interconnect lines.

As new materials are introduced to improve and progress semiconductor manufacturing for BEOL, new problems arise with the use of such new materials. One such problem is the adhesion strength between materials being too weak to withstand the forces exerted on the wafer during chemical mechanical polishing (CMP), which can cause metal plugs or new formed metal features to be extracted or removed from a corresponding via or trench. Such unspecified removal is typically undesirable because it can reduce yield and increase manufacturing costs and waste. Thus, there is a need to address and solve such problems with new BEOL process flows.

### SUMMARY

In an embodiment of the present disclosure, a method for making a semiconductor device can include: providing a first intermediate structure comprising a first dielectric layer, the first dielectric layer having a via hole formed therein, wherein the via hole opens to an underlying conductive structure, wherein the first dielectric layer comprises a first low-k dielectric material having a first dielectric constant less than 3.9; forming a conductive liner such that the conductive liner comprises a line liner portion directly on a first-dielectric-layer top surface of the first dielectric layer and a via sidewall liner portion directly on a sidewall of the via hole; and forming an interconnect structure comprising ruthenium directly on the conductive liner using a subtractive interconnect formation process such that the interconnect structure comprises a via plug portion at a first interconnect level in the via hole and a line portion at a second interconnect level extending on the first-dielectric-layer top surface of the first dielectric layer, wherein the via plug portion is contiguous and integral with the line portion such that the line portion is electrical connected with the underlying conductive structure via the via plug portion, wherein the via sidewall liner portion is between the via plug portion of the interconnect structure and the sidewall of the via hole, and wherein the line liner portion is between the line portion of the interconnect structure and the first-dielectric-layer top surface of the first dielectric layer.

In an embodiment of the present disclosure, a method for making a semiconductor device can include: providing a first intermediate structure comprising a first dielectric layer, the first dielectric layer having a via hole formed therein, wherein the via hole opens to an underlying conductive structure, wherein the first dielectric layer comprises a first low-k dielectric material having a first dielectric constant less than 3.9; forming a conductive liner such that the conductive liner comprises a line liner portion directly on a first-dielectric-layer top surface of the first dielectric layer and a via sidewall liner portion directly on a sidewall of the via hole; and forming an interconnect structure comprising ruthenium directly on the conductive liner using a subtractive interconnect formation process such that the interconnect structure comprises a via plug portion at a first interconnect level in the via hole and a line portion at a second interconnect level extending on the first-dielectric-layer top surface of the first dielectric layer, wherein the via plug portion is contiguous and integral with the line portion such that the line portion is electrical connected with the underlying conductive structure via the via plug portion, wherein the via sidewall liner portion is between the via plug portion of the interconnect structure and the sidewall of the via hole, and wherein the line liner portion is between the line portion of the interconnect structure and the first-dielectric-layer top surface of the first dielectric layer, wherein the forming of the conductive liner comprises a first conductive-liner-deposition stage and a second conductive-liner-deposition stage, wherein the first conductive-liner-deposition stage comprises depositing a first conductive-liner portion on the first intermediate structure such that a first-via-sidewall-liner portion of the via sidewall liner portion has a first sidewall-portion thickness on the sidewall of the via hole, wherein the second conductive-liner-deposition stage comprises sputtering the first conductive-liner portion with an inert gas using a high bias to remove via-bottom portions of the first conductive-liner portion at a bottom of the via hole and depositing a second conductive-liner portion on the first-via-sidewall-liner portion of the via sidewall liner portion such that the via sidewall liner portion has a second sidewall-portion thickness on the sidewall of the via hole, to form a second intermediate structure, wherein the second sidewall-portion thickness is greater than the first sidewall-portion thickness.

In an embodiment of the present disclosure, a semiconductor device can include: a first dielectric layer having a via hole therein, wherein the first dielectric layer comprises a first low-k dielectric material having a first dielectric constant less than 3.9; an interconnect structure comprising a via plug portion at a first interconnect level in the via hole and a line portion at a second interconnect level extending on a top surface of the first dielectric layer, wherein the via plug portion is contiguous and integral with the line portion, and wherein the interconnect structure comprises ruthenium; and a liner comprising a via sidewall liner portion and a line liner portion, wherein the via sidewall liner portion is directly on the first dielectric layer at a sidewall of the via hole between the via plug portion of the interconnect structure and the sidewall of the via hole, wherein the line liner portion is directly on the top surface of the first dielectric layer between the line portion of the interconnect structure and the top surface of the first dielectric layer, wherein at least part of the interconnect structure is directly on the liner, and wherein the liner comprises niobium.

### BRIEF DESCRIPTION OF THE DRAWINGS

For a more complete understanding of the present disclosure, and advantages thereof, reference is now made to the following descriptions of example embodiments taken in conjunction with the accompanying drawings, in which:

FIGS. 1A to 1H are cross-section views illustrating intermediate structures of a semiconductor device made using a method according to an embodiment of the present disclosure;

FIGS. 2A to 2I are cross-section views illustrating intermediate structures of a semiconductor device made using a method according to an embodiment of the present disclosure;

FIGS. 3A to 3C are cross-section views illustrating intermediate structures of a semiconductor device made using a method according to an embodiment of the present disclosure;

FIGS. 4A to 4C are cross-section views illustrating intermediate structures of a semiconductor device made using a method according to an embodiment of the present disclosure;

FIGS. 5A to 5B are cross-section views illustrating intermediate structures of a semiconductor device made using a method according to an embodiment of the present disclosure;

FIG. 6 is a flow chart of a method of making a semiconductor device in accordance with an embodiment of the present disclosure;

FIG. 7 is a flow chart of a method of making a semiconductor device in accordance with an embodiment of the present disclosure;

FIG. 8 is a flow chart of a method of making a semiconductor device in accordance with an embodiment of the present disclosure;

FIG. 9 is a flow chart of a method of making a semiconductor device in accordance with an embodiment of the present disclosure;

FIG. 10 is a flow chart of a method of making a semiconductor device in accordance with an embodiment of the present disclosure;

FIG. 11 is a flow chart of a method of making a semiconductor device in accordance with an embodiment of the present disclosure; and

FIG. 12 is a flow chart of a method of making a semiconductor device in accordance with an embodiment of the present disclosure.

### DETAILED DESCRIPTION OF ILLUSTRATIVE EMBODIMENTS

Referring now to the drawings, in which like reference numbers can be used herein to designate like or similar elements throughout the various views, illustrative and example embodiments are shown and described. The figures are not drawn to scale, and in some instances the drawings are exaggerated or simplified in places for illustrative purposes. One of ordinary skill in the art can appreciate many possible applications and variations for other embodiments based on the following illustrative and example embodiments provided in the present disclosure. A number of example embodiments of the present disclosure are described below. Other embodiments can also be understood from the entirety of the specification as well as the claims filed herein. It can be understood that various features of different embodiments can be combined.

In the present disclosure, terms such as “first”, “second”, and the like, may be used to describe various components, but the components are not necessarily limited by such terms, for example, regarding order, sequence, importance, or number of such components possible in an embodiment. Such terms can be used merely for the purpose of distinguishing one component from other components in a given embodiment or group of embodiments. For example, a first component may be referred to as a second component, and similarly, a second component may also be referred to as a first component without departing from the scopes of rights according to the present disclosure.

In the present disclosure and drawings, labels such as “M0”, “M1”, and “M2” can be used to describe various interconnect levels in the drawings, which can be commonly referred to as “metallization levels” in the semiconductor industry (even if there are conductive materials that are not metals included in the interconnect structure). However, a labeling of interconnect levels in the drawings for describing a given example embodiment of the present disclosure may not correspond to the labels used to name or identify actual interconnect levels, or to define an actual vertical location thereof, in an actual implementation of an embodiment. Thus, such labels used in the present specification do not necessarily limit an interconnect level to an actual interconnect level that implements an embodiment of the present disclosure. For example, an interconnect level labeled “M1” in present specification may correspond to an actual interconnect level located at or designated as level M5 while still being in accordance with an embodiment of the present disclosure.

Recent research and development for BEOL processes are exploring the use of ruthenium for BEOL interconnects. One advantage of using ruthenium for relatively smaller vias is better conductivity compared with copper-based via structures. Another advantage of using ruthenium is that ruthenium does not require a barrier layer relative to dielectric materials of BEOL structures. However, research has shown that ruthenium has relatively weak adhesion to some commonly-used low-k dielectric materials (e.g., dielectric materials having a dielectric constant (k) less than 3.9). During chemical-mechanical polishing (CMP), ruthenium formed directly on some commonly-used low-k dielectric materials has caused the ruthenium via plug and/or interconnect line to be dislodged, moved (sometimes referred to a line wiggle), or delaminated.

Another issue with using ruthenium together with low-k dielectric materials in BEOL is that ruthenium is typically best etched with an oxide-based chemical. However, such oxide-based chemicals can greatly damage and/or change the electrical properties of some commonly-used low-k dielectric materials. For example, during a subtractive semi-damascene process flow for forming a ruthenium interconnect structure for BEOL, patterning and etching ruthenium using an oxide-based chemical can damage and/or change the electrical properties of some commonly-used low-k dielectric materials.

Through research and development, the inventors have developed BEOL process flows and structures, in accordance with embodiments of the present disclosure, that can solve the problems outlined above when using a subtractive semi-damascene process flow for forming a ruthenium interconnect structure for BEOL. An embodiment of the present disclosure can improve the adhesion strength of a ruthenium interconnect structure relative to low-k dielectric material by incorporating a conductive liner (e.g., niobium). Using an embodiment of the present disclosure, a conductive liner (e.g., niobium) can protect an underlying low-k dielectric material and act as an etch stop layer during the etching of ruthenium in a subtractive semi-damascene process flow for forming a ruthenium interconnect structure for BEOL.

In some embodiments of the present disclosure, a method for forming a semiconductor device can include: providing a first intermediate structure including a first dielectric layer, the first dielectric layer having a via hole formed therein, where the first dielectric layer includes a low-k dielectric material; forming a conductive liner such that the conductive liner includes a line liner portion directly on a top surface of the first dielectric layer and a via sidewall liner portion directly on a sidewall of the via hole; and forming a ruthenium interconnect structure directly on the conductive liner using a subtractive interconnect formation process such that the interconnect structure includes a via plug portion in the via hole and a line portion extending on the top surface of the first dielectric layer, where the via sidewall liner portion is between the via plug portion and the sidewall of the via hole, and where the line liner portion is between the line portion and the top surface of the first dielectric layer.

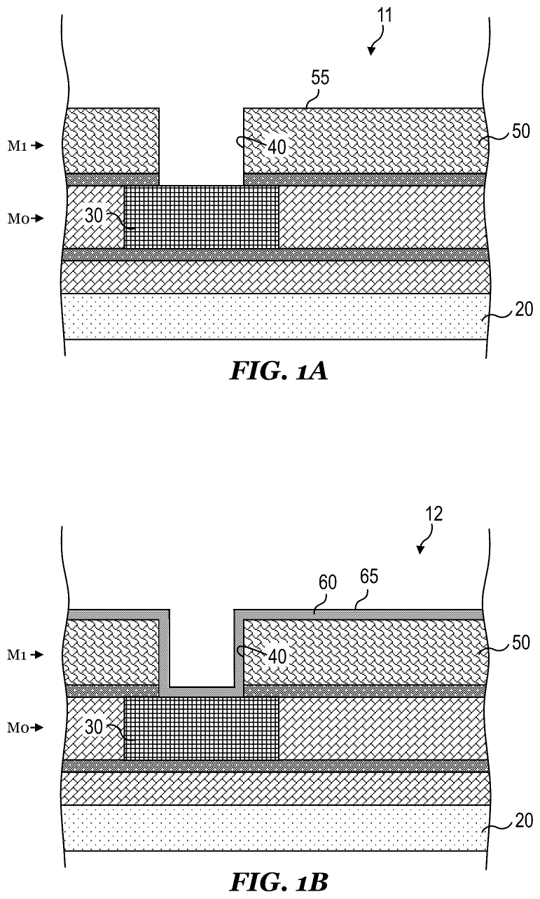

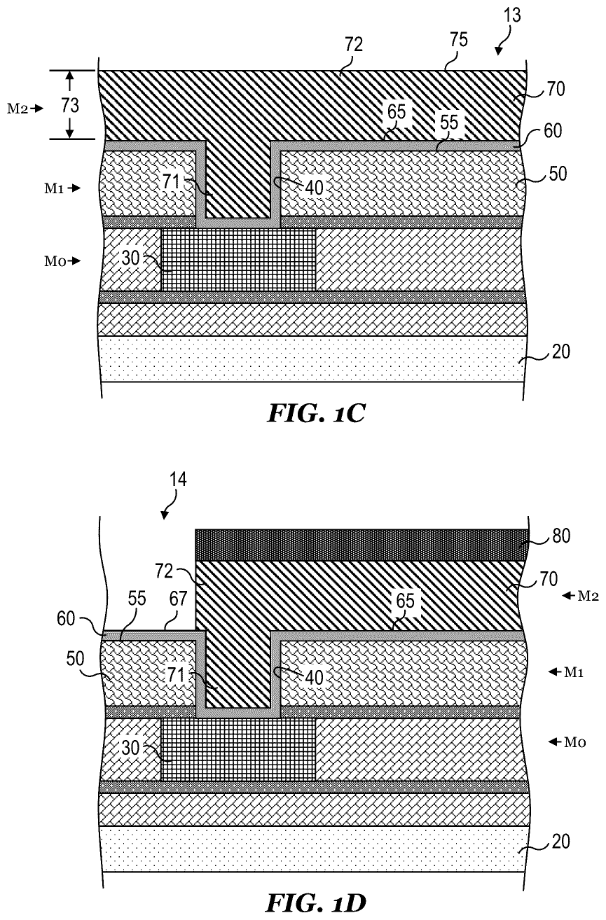

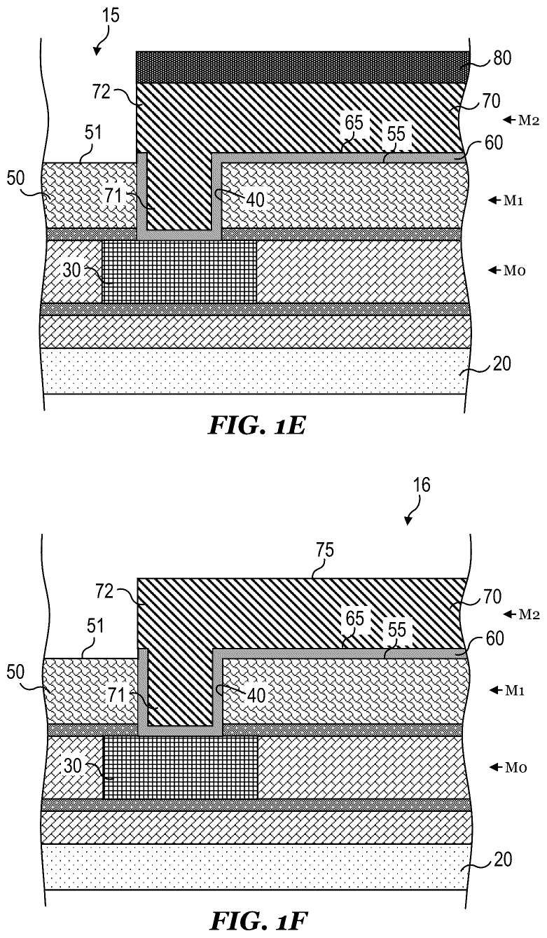

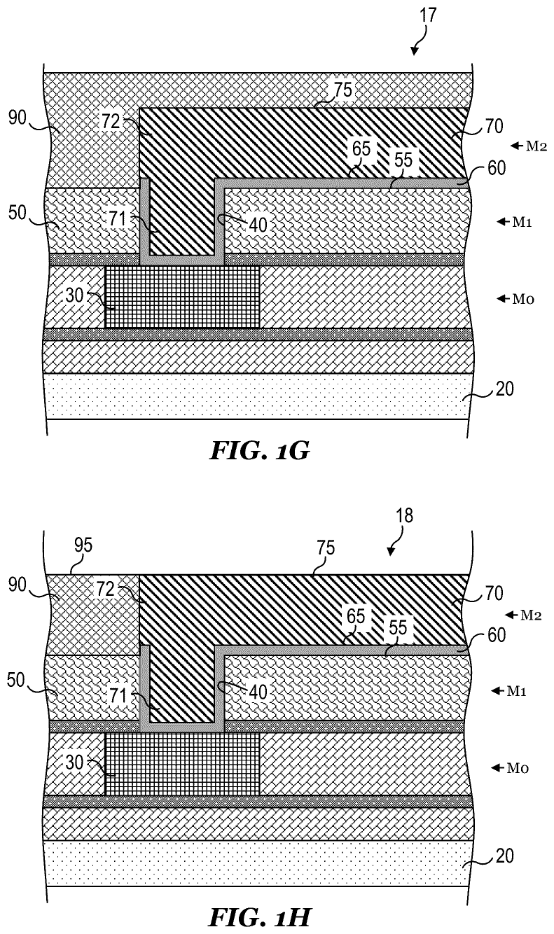

FIGS. 1A to 5B are various cross-section views illustrating various intermediate structures during various methods of making a semiconductor device according to some example embodiments of the present disclosure. For simplification and illustration purposes, FIGS. 1A to 5B are merely showing some portions of a semiconductor device as intermediate structures that can be relevant to a method of making the semiconductor device according to an example embodiment of the present disclosure. For example, in FIGS. 1A to 5B, to simplify the drawings, as can be readily understood by one of ordinary skill in the pertinent art, additional layers and structures of a semiconductor device made before, under, below, or adjacent to the intermediate structures shown in the drawings are omitted, which can include any structures, types, and circuits of semiconductor devices, such as additional interconnects, additional vias, additional trenches, additional interlayer dielectric layers, additional intermetal dielectric layers, additional backend-of-line (BEOL) stage(s) or level(s), frontend-of-line (FEOL) stages or levels, transistors, diodes, capacitors, resistors, inductors, integrated circuits, memory cells, logic, processor portions, digital devices, analog devices, semiconductor wafer, silicon-on-insulator wafer, or combinations thereof, for example. Also in FIGS. 1A to 5B, to simplify the drawings, as can be readily understood by one of ordinary skill in the pertinent art, additional layers and structures of a substrate for a semiconductor device made after, over, above, or adjacent to the intermediate structures shown in the drawings are omitted, which can include any structures, types, and circuits of semiconductor devices, such as additional interconnects, additional vias, additional trenches, additional interlayer dielectric layers, additional intermetal dielectric layers, additional backend-of-line (BEOL) stage(s) or level(s), passivation layers, contact pads, local interconnects, global interconnects, wire bonding, packaging, or combinations thereof, for example.

In an actual completed semiconductor device cross-section, the intermediate structures, which are illustrated and represented in the drawings of the present disclosure in a simplified manner as having squared edges and/or linear shapes, can be actually more rounded, have rounded corners, more curved shaped, and less linear shaped, and can be perhaps even difficult to visually see even in an image taken with a scanning electron microscope (SEM) or a transmission electron microscope (TEM) due the extremely small size, thickness, and scale of some layers and resulting features (e.g., some on the scale of atoms to 5 nanometers in size), or may be removed during processing and little or no remnants of certain layers, features, or portions in the final semiconductor device publicly sold and used.

FIGS. 1A to 1H are cross-section views illustrating intermediate structures of a semiconductor device, having interconnect levels M0, M1, and M2, made using a method according to an embodiment of the present disclosure. Referring to FIG. 1A, a first intermediate structure 11 can include multiple levels/layers of insulating layers on a substrate 20. In the present disclosure, substrate 20 can be a very generic and simplified representation of any semiconductor structures that can be below the BEOL structure, such as a wafer, transistors, logic devices, power devices, digital circuits, analog circuits, or any combination thereof, for example, or any suitable/feasible structure, as can be apparent to one of ordinary skill in the art for which the present disclosure pertains (and thus the details of which are omitted here). Hence, the simplified representation of the substrate 20 in the drawings is not intended to be necessarily limiting.

Referring to FIG. 1A, a first intermediate structure 11 can include an M0 level including an underlying conductive structure 30. The underlying conductive structure 30 in the drawings is shown as a single block of material merely to simplify the drawings, as the underlying conductive structure 30 in some embodiments can include multiple layers of multiple materials (e.g., barrier layer, adhesion layer, metal fill, etc.) or any suitable/feasible structure, as can be apparent to one of ordinary skill in the art for which the present disclosure pertains (and thus the details of which are omitted here). Hence, the simplified representation of the underlying conductive structure 30 in the drawings is not intended to be necessarily limiting. In some embodiments, some of or most of a top surface of the underlying conductive structure 30 can be a metal material, such as ruthenium, copper, cobalt, tungsten, or any combination thereof, for example.

Referring to FIG. 1A, a first dielectric layer 50 can include a via hole 40 formed therein at interconnect level M1. In some embodiments, the first dielectric layer 50 can be a single layer of one material, a single layer of a mix of multiple materials, multiple layers of one material, multiple layers of a same material or mix of multiple materials, or multiple layers of different materials, for example. In some embodiments, the material(s) of a given first dielectric layer 50 can be selected in view of providing acceptable dielectric properties (e.g., low-k), and fitting within the process integration flow and device electrical characteristics (e.g., thermal budgets, thermal stress mismatching, adhesion, electrical properties, parasitic capacitance, etc.). In some embodiments, such material(s) of a given first dielectric layer 50 can include a suitable silicon dioxide (SiO₂) and structural variations thereof (e.g., flowable oxide, gel, including large air pockets, porous, etc.), for example.

In some embodiments, such material(s) of a given first dielectric layer 50 can include a low-k dielectric material, such as silicon oxycarbide (SiOC), silicon oxycarbonitride (SiOCN), fluorinated silicon dioxide (FSG), organosilicate glass (OSG), silicon-carbon-oxygen-hydrogen (SiCOH), porous SiCOH, hydrogen silsesquioxane (HSQ), Methylsilsesquioxane (MSQ), nanoporous silicon dioxide, organic polymer having a third dielectric constant less than 2.6, silica-based aerogel having a fourth dielectric constant less than 2.4, spin-on organic material having a fifth dielectric constant less than 2.6, benzocyclobutene (BCB), or organosilicate material having a sixth dielectric constant less than 2.7, layers thereof, mixtures thereof, laminates thereof, or generally any combination thereof, for example.

Thus, because the first dielectric layer 50 of an embodiment can include any number or combination of layers and materials (e.g., low-k dielectric material, etch stop layer, barrier layer, etc.), or any suitable/feasible structure (as can be apparent to one of ordinary skill in the art for which the present disclosure pertains and hence the details of which are omitted here), the simplified representation of the first dielectric layer 50 in the drawings can be considered a simplified illustration and is not intended to be necessarily limiting.

In some embodiments, the first dielectric layer 50 can have a thickness in a range of 30 nm to 100 nm, while the via hole 40 can have a critical dimension (e.g., diameter) in a range of 5 nm to 20 nm, which can be a relatively high aspect ratio via hole. For example, in some embodiments, the first dielectric layer 50 can have a thickness of about 60 nm and the via hole 40 can have a diameter of about 10 nm.

Photolithography and patterning masks can be used and removed in a process flow for forming the via hole 40 of FIG. 1A, as can be apparent to one of ordinary skill in the art, and thus the details of which are omitted herein.

Referring to FIG. 1B, a conductive liner 60 can be deposited over the first intermediate structure 11 of FIG. 1A. In some embodiments, the conductive liner 60 can be deposited so that it is conformal to the intermediate structure 11. In some embodiments, a conductive liner 60 can be or can include a conductive material that is selective to being etched using an oxide-based chemical used for etching ruthenium (e.g., ruthenium etches relatively faster than the selected conductive material of the conductive liner 60).

As will be described in more detail below, in some embodiments, the conductive liner 60 can be formed using physical vapor deposition (PVD), plasma enhanced physical vapor deposition (PEPVD), chemical vapor deposition (CVD), plasma enhanced chemical vapor deposition (PECVD), atomic layer deposition (ALD), vapor deposition, or any combination thereof, for example.

Research and development have shown that niobium can be used for a conductive liner 60 in an embodiment of the present disclosure. For example, comparing niobium to a conventional liner, such as titanium nitride, niobium has better conductivity. For example, titanium nitride has a bulk resistivity of 25 μΩ·cm and niobium has a bulk resistivity of 15.2 μΩ·cm. In the example embodiments described in the present disclosure, the conductive liner 60 can be or will be niobium. However, in other potential embodiments, the conductive liner 60 can be other materials. For example, in some embodiments, a conductive liner 60 can be or can include at least one metal, or alloy thereof, of the following group: niobium, aluminum, aluminum oxide, tungsten, tantalum, and titanium.

Still referring to FIG. 1B, in an example embodiment of the present disclosure, a conductive liner 60 can be conformally deposited over the intermediate structure 11 of FIG. 1A, to form a second intermediate structure 12 of FIG. 1B. For example, in an embodiment, a conductive liner 60 can be made of niobium and can have a thickness in a thickness range of 1 nm to 3 nm. In some embodiments, a conductive liner 60 can continuously and contiguously cover the sidewalls of the via hole 40, the bottom of the via hole 40, and a top surface 55 of the first dielectric layer 50. In some embodiments, a conductive liner 60 can have a minimum thickness for which the conductive liner 60 continuously covers at least part of the sidewalls of the via hole 40, such as 1 nm to 3 nm (depending upon the operation used for depositing/forming the conductive liner 60). In some embodiments, a conductive liner 60 can have a minimum thickness for which the conductive liner 60 continuously covers a top surface 55 of the first dielectric layer 50. In some embodiments, a thickness of a conductive liner 60 can vary between a via sidewall liner portion on a sidewall of the via hole 40 and a line liner portion on a top surface 55 of the first dielectric layer 50. Also, in some embodiments, a thickness of a conductive liner 60 at the bottom of the via hole 40 can be in a range of 0 nm (none) to 3 nm (depending upon the operation used for depositing/forming the conductive liner 60), for example.

Referring to FIG. 1C, a conductive material for an interconnect structure 70 can be formed directly on the conductive liner 60. The conductive material for the interconnect structure 70 can be ruthenium. In some embodiments, metal material(s) of the interconnect structure 70 can include ruthenium, molybdenum, niobium, tungsten, tantalum, aluminum, alloys thereof, layers thereof, mixtures thereof, laminates thereof, or generally any combination thereof, for example. By using materials such as ruthenium and/or molybdenum, the use of a barrier layer can be omitted with respect to dielectric layer materials. However, while the use of ruthenium and/or molybdenum can be desirable for filling smaller diameter and/or higher aspect ratio via holes, other issues in the process flow using such materials can arise, such as oxidation and interface resistance, which can introduce additional processing steps and intervening layers.

In the example embodiments described in the present disclosure, the conductive material for an interconnect structure 70 will be ruthenium. However, in other potential embodiments, the conductive material for an interconnect structure 70 can be other materials, such as an alloy of ruthenium or ruthenium combined with another material, for example.

Referring to FIG. 1C, the via hole 40 can be overfilled with ruthenium for an operation of forming an interconnect structure 70, such that a first thickness 73 of the ruthenium is formed on a conductive-liner top surface 65 of the second intermediate structure 12 of FIG. 1B, to form a third intermediate structure 13 of FIG. 1C. The conductive-liner top surface 65 can be above the via hole 40. A ruthenium top surface 75 of the ruthenium can be separated from the conductive-liner top surface 65 by the first thickness 73. For a subtractive semi-damascene process flow, the third intermediate structure 13 of FIG. 1C can have a blanket top surface 75 of ruthenium, for example. The ruthenium of the interconnect structure 70 can be formed using any suitable deposition process, such as physical vapor deposition (PVD), plasma enhanced physical vapor deposition (PEPVD), chemical vapor deposition (CVD), plasma enhanced chemical vapor deposition (PECVD), atomic layer deposition (ALD), vapor deposition, or any combination thereof, for example.

Still referring to FIG. 1C, an interconnect structure 70 can have a via plug portion 71 at a first interconnect level M1 in the via hole 40, and a line portion 72 at a second interconnect level M2 extending directly on a top surface 65 of the conductive liner 60 (extending indirectly on the top surface 55 of the first dielectric layer 50). The via plug portion 71 can be contiguous and integral with the line portion 72 such that the line portion 72 is electrical connected with the underlying conductive structure 30 via the via plug portion 71 (and via the conductive liner 60 in some embodiments). A via sidewall liner portion of the conductive liner 60 can be between the via plug portion 71 of the interconnect structure 70 and the sidewall of the via hole 40. A line liner portion of the conductive liner 60 can be between the line portion 72 of the interconnect structure 70 and a top surface 55 of the first dielectric layer 50. A bottom liner portion of the conductive liner 60 can be between a via bottom portion of the interconnect structure 70 and the underlying conductive structure 30.

Referring to FIG. 1D, a mask 80 can be formed and patterned on the top surface 75 of the ruthenium of the interconnect structure 70. The mask 80 in the drawings is shown as a single block of material merely to simplify the drawings, as the mask 80 in some embodiments can include multiple layers of multiple materials or any suitable/feasible structure, as can be apparent to one of ordinary skill in the art for which the present disclosure pertains (and thus the details of which are omitted here). Hence, the simplified representation of the mask 80 in the drawings is not intended to be necessarily limiting. Photolithography and patterning of the mask 80 can be used.

Referring to FIG. 1D, using the mask 80 for establishing a pattern, the ruthenium of the interconnect structure 70 can be etched using any suitable etch chemistry, etching tool, and etching process, to form a fourth intermediate structure 14. In some embodiments, the ruthenium of the interconnect structure 70 can be etched using an oxide-based etch chemistry and reactive ion etching (RIE), for example. In some embodiments, the ruthenium of the interconnect structure 70 can be etched using an oxygen plasma and RIE, for example. Because the conductive liner 60 can be a material with etch selectivity with respect to an etch chemistry used for etching the ruthenium of the interconnect structure 70, the conductive liner 60 can act as an etch stop layer during/for the etching of the ruthenium of the interconnect structure 70. The ruthenium of the interconnect structure 70 can be etched and patterned to expose a first-exposed-conductive-liner part 67 of the conductive liner 60 at the conductive-liner top surface 65 using the mask 80 to pattern the ruthenium forming the line portion 72 of the interconnect structure 70. The first-exposed-conductive-liner part 67 of the conductive liner 60 can be used as an etch-stop layer to protect the first dielectric layer 50 during the etching of the ruthenium of the interconnect structure 70.

Referring to FIG. 1E, the first-exposed-conductive-liner part 67 of the conductive liner 60 adjacent the line portion 72 of the interconnect structure 70 (see FIG. 1D) can be removed to expose a first-exposed-dielectric-layer part 51 of the first dielectric layer 50 at the first-dielectric-layer top surface 55 of the first dielectric layer 50 adjacent the line portion 72 of the interconnect structure 70, to form a fifth intermediate structure 15. In some embodiments, the ruthenium of the interconnect structure 70 can be etched with a first etch chemistry that is selective to etching the ruthenium of the interconnect structure 70 much faster than the conductive liner 60 (see, e.g., FIG. 1D), and then the conductive liner 60 can be etched with a second etch chemistry to remove the first-exposed-conductive-liner part 67 of the conductive liner 60 adjacent the line portion 72 of the interconnect structure 70 (as illustrated in FIG. 1E).

In some embodiments, the ruthenium of the interconnect structure 70 can be etched with a first etch chemistry that is selective to etching the ruthenium of the interconnect structure 70 much faster than the conductive liner 60 (see, e.g., FIG. 1D) in a first etch chamber, and then, without moving the wafer from the first etch chamber, the conductive liner 60 can be etched with a second etch chemistry in the first etch chamber to remove the first-exposed-conductive-liner part 67 of the conductive liner 60 adjacent the line portion 72 of the interconnect structure 70 (as illustrated in FIG. 1E), where the second etch chemistry differs from the first etch chemistry. Hence, an embodiment of the present disclosure can provide an advantage of etching the ruthenium of the interconnect structure 70 and etching the first-exposed-conductive-liner part 67 of the conductive liner 60 in a same chamber, simply by changing the etch chemistry and/or the etch parameters in the etch chamber.

For example, in some embodiments, the ruthenium of the interconnect structure 70 can be etched with a first etch chemistry in a first chamber of a first tool, where the first etch chemistry is an oxide-based etch chemistry (e.g., O₂+Cl₂, O₂+BCl₃, O₂+CF₄ plasma etching or RIE, or oxygen plasma including chlorine RIE) that is selective to etch ruthenium faster than niobium, and niobium material of the first-exposed-conductive-liner part 67 of the conductive liner 60 can be etched with a second etch chemistry (e.g., wet etch with diluted hydrofluoric acid (DHF) or RIE with fluorine-based etch chemistry) that is selective to etching niobium faster than etching low-k dielectric material. For example, a second etch chemistry used for etching niobium (for the conductive liner 60) can be a non-oxide based etch chemistry (e.g., SF₆, CF₄, Cl₂/BCl₃, or NF₃ plasma etching or RIE) (e.g., DHF, HF+H₂O₂+H₂O, HNO₃+HF, or H₃PO₄ wet etching) or a relatively lower oxide-based etch chemistry (compared to that used for etching ruthenium) (e.g., SF₆+O₂, CF₄+O₂, CHF₃+O₂ plasma etching or RIE) (e.g., HF+H₂O₂, HF+H₂O₂+H₂O, HNO₃+HF, or H₃PO₄ wet etching), which is much less harmful to a low-k dielectric material of the first dielectric layer 50 compared to the first etch chemistry for ruthenium. For example, in some embodiments, a conductive liner 60 made of niobium can be etched with a Standard Clean 1 (SC1) wet etching (e.g., NH₄OH+H₂O₂+H₂O). However, wet etching with DHF or SC1 can cause undercutting of the niobium (etching niobium under ruthenium), and thus precise timing (e.g., less than 2 minutes) may be needed to use such wet etches.

Referring to FIG. 1F, the mask 80 can be removed from a top surface 75 of the interconnect structure 70, to form a sixth intermediate structure 16. In some embodiments, the mask 80 can be removed before etching the first-exposed-conductive-liner part 67 of the conductive liner 60 adjacent the line portion 72 of the interconnect structure 70. In some embodiments, the mask 80 can be removed after etching the first-exposed-conductive-liner part 67 of the conductive liner 60 adjacent the line portion 72 of the interconnect structure 70. In some embodiments, part or all of the mask 80 can be removed while etching part or all of the first-exposed-conductive-liner part 67 of the conductive liner 60 adjacent the line portion 72 of the interconnect structure 70. In some embodiments, the mask 80 can be removed (e.g., using a third etch chemistry and/or other removal process) in a same etch chamber (without moving the wafer) as used to etch the ruthenium of the interconnect structure 70 with a first etch chemistry and/or to etch the first-exposed-conductive-liner part 67 of the conductive liner 60 adjacent the line portion 72 of the interconnect structure 70 with a second etch chemistry. The mask 80 can be removed by a wet clean, for example. An oxide hard mask can be removed using a diluted hydrofluoric acid (DHF), for example. The process used to remove the mask 80 can depend on the material(s) used for the mask 80 and the first dielectric layer 50, to avoid damaging the first dielectric layer 50 during the removal of the mask 80. The mask 80 can be removed using any suitable/feasible process, as can be apparent to one of ordinary skill in the art for which the present disclosure pertains (and thus more details of which are omitted here).

Referring to FIG. 1G, a second dielectric layer 90 can be formed or deposited on the sixth intermediate structure 16 of FIG. 1F, to form a seventh intermediate structure 17 in FIG. 1G. More specifically, a second dielectric layer 90 can be formed or deposited on the first-exposed-dielectric-layer part 51 of the first dielectric layer 50 and on the line portion 72 of the interconnect structure 70. A portion of the second dielectric layer 90 can be formed or deposited directly on the first-exposed-dielectric-layer part 51 of the first dielectric layer 50. A portion of the second dielectric layer 90 can be formed or deposited directly on the line portion 72 of the interconnect structure 70.

In some embodiments, the second dielectric layer 90 can be a single layer of one material, a single layer of a mix of multiple materials, multiple layers of one material, multiple layers of a same material or mix of multiple materials, or multiple layers of different materials, for example. In some embodiments, the material(s) of a given second dielectric layer 90 can be selected in view of providing acceptable dielectric properties (e.g., low-k), and fitting within the process integration flow and device electrical characteristics (e.g., thermal budgets, thermal stress mismatching, adhesion, electrical properties, parasitic capacitance, etc.). In some embodiments, such material(s) of a given second dielectric layer 90 can include a suitable silicon dioxide (SiO₂) and structural variations thereof (e.g., flowable oxide, gel, including large air pockets, porous, etc.), for example.

In some embodiments, such material(s) of a given second dielectric layer 90 can include a low-k dielectric material, such as silicon oxycarbide (SiOC), silicon oxycarbonitride (SiOCN), fluorinated silicon dioxide (FSG), organosilicate glass (OSG), silicon-carbon-oxygen-hydrogen (SiCOH), porous SiCOH, hydrogen silsesquioxane (HSQ), Methylsilsesquioxane (MSQ), nanoporous silicon dioxide, organic polymer having a third dielectric constant less than 2.6, silica-based aerogel having a fourth dielectric constant less than 2.4, spin-on organic material having a fifth dielectric constant less than 2.6, benzocyclobutene (BCB), or organosilicate material having a sixth dielectric constant less than 2.7, layers thereof, mixtures thereof, laminates thereof, or generally any combination thereof, for example.

Thus, because the second dielectric layer 90 of an embodiment can include any number or combination of layers and materials (e.g., low-k dielectric material, etch stop layer, barrier layer, etc.), or any suitable/feasible structure (as can be apparent to one of ordinary skill in the art for which the present disclosure pertains and hence the details of which are omitted here), the simplified representation of the second dielectric layer 90 in the drawings can be considered a simplified illustration and is not intended to be necessarily limiting.

Referring to FIG. 1H, a second-dielectric-layer top surface 95 of the second dielectric layer 90 and a line-portion top surface 75 of the line portion 72 of the interconnect structure 70 can be planarized (e.g., using CMP), to form an eighth intermediate structure 18.

In some embodiments, the second dielectric layer 90 can have a thickness in a range of 30 nm to 100 nm, for example. In some embodiments, the second dielectric layer 90 can have a thickness of about 60 nm, for example.

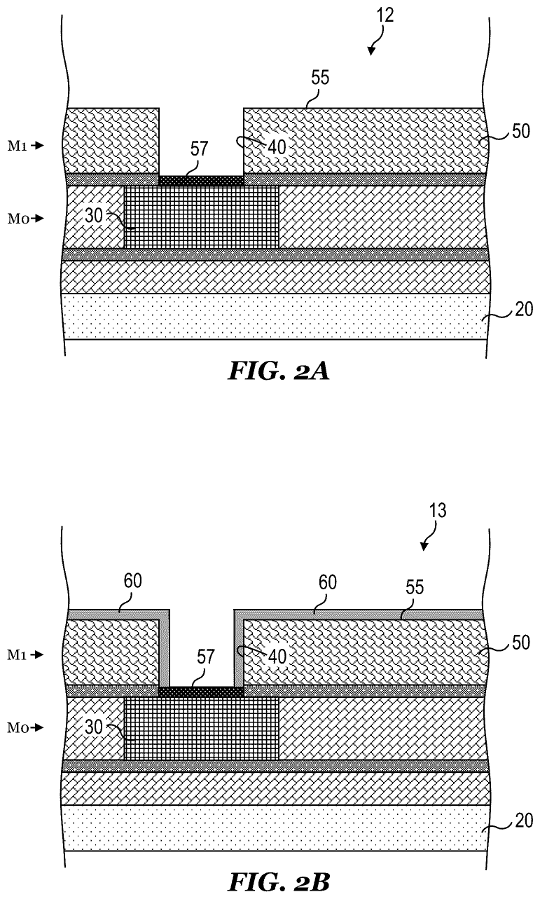

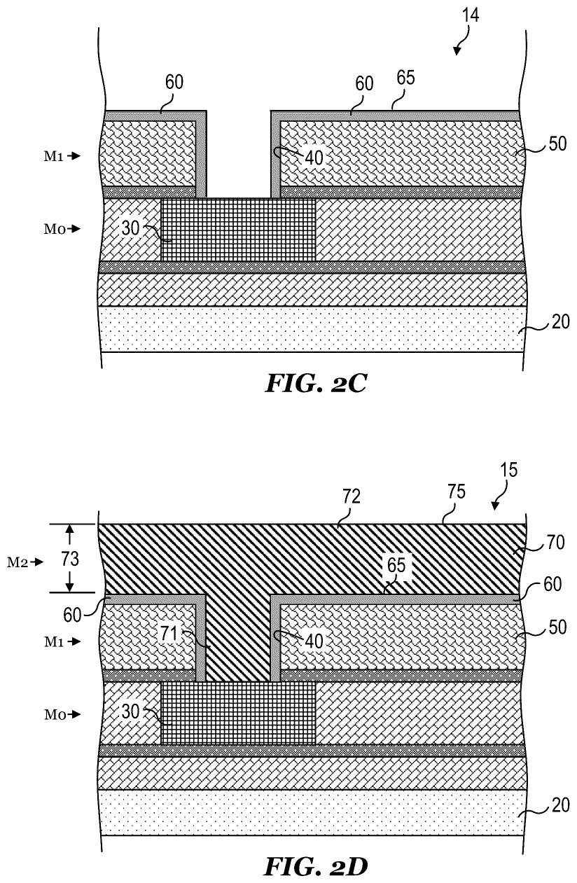

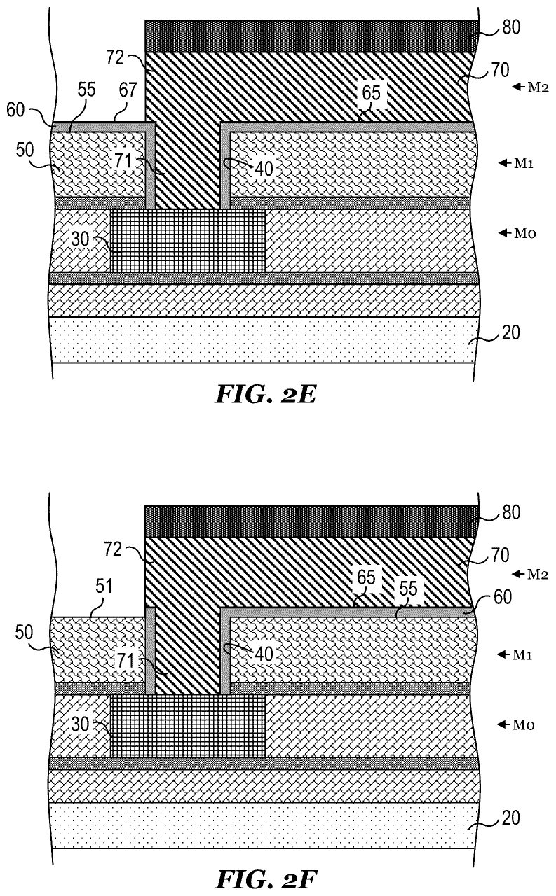

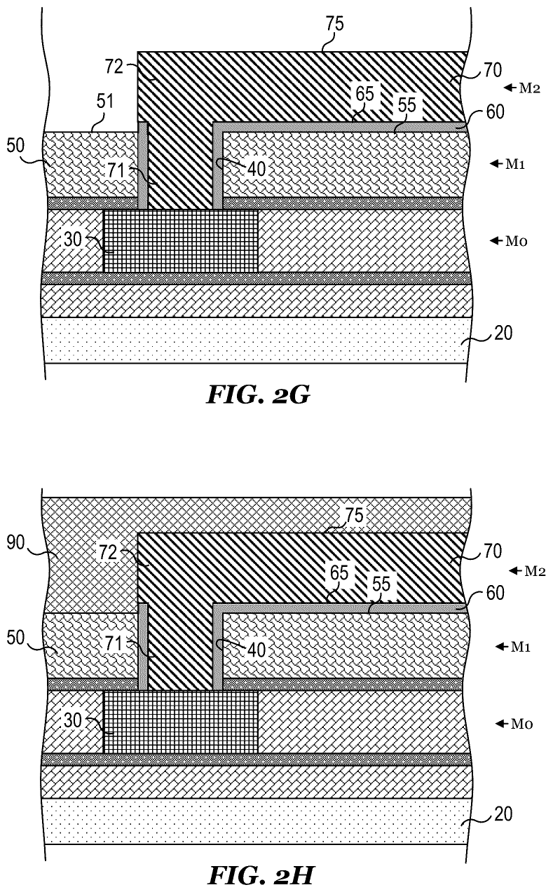

FIGS. 2A to 2I are cross-section views illustrating intermediate structures of a semiconductor device made using a method according to an embodiment of the present disclosure. In some embodiments of the present disclosure, the forming of a conductive liner 60 in a method for forming a semiconductor device can include: selectively depositing a deposition inhibitor 57 (e.g., self-assembled monolayer (SAM) or small molecule inhibitor (SMI)) on an underlying conductive structure 30 at a bottom of a via hole 40; selectively and conformally depositing a line liner portion of the conductive liner 60 directly on a first-dielectric-layer top surface 55 of a first dielectric layer 50 and a via sidewall liner portion directly on a sidewall of the via hole 40; and removing the deposition inhibitor 57 to expose the underlying conductive structure 30.

Beginning with a first intermediate structure 11 of FIG. 1A, for example, a deposition inhibitor 57 can be formed or selectively deposited on the underlying conductive structure 30 at a bottom of the via hole 40, to form a second intermediate structure 12 of FIG. 2A. The deposition inhibitor 57 can be used as a blocking layer to mask a top surface of the underlying conductive structure 30.

A SAM and/or SMI can be used as a deposition inhibitor 57 in some embodiment, for example. Generally, SMIs can be used to selectively prevent material deposition in certain areas during a deposition process (e.g., ALD, CVD) by temporarily modifying the surface chemistry of specific regions, which can prevent precursor molecules from bonding and reacting. SMIs can be organic molecules (e.g., alkanethiols, silanes) or inorganic compounds tailored to specific deposition process parameters, for example. Octadecylphosphonic acid (ODPA) can be used for metal surface blocking, for example.

Generally, SAMs are molecular assemblies that can selectively form on certain material surfaces (e.g., metal surfaces for some example embodiments) through adsorption, organizing into ordered domains of varying sizes. A SAM typically consists of a molecule with a head group, a tail group, and a functional end group. Formation of a SAM on a certain surface (dependent on the SAM formulation selected for a given surface material) can occur via chemisorption of the head groups from the vapor phase, either at room temperature or above. Subsequently, the tail groups organize slowly. Initially, at low molecular density on the surface, adsorbate molecules may aggregate into a disordered mass or form an ordered two-dimensional “lying down phase.” As the molecular coverage increases, typically over minutes to hours, three-dimensional crystalline or semicrystalline structures can selectively develop on the given certain surfaces. The head groups can assemble directly on the given certain surfaces, while the tail groups can extend away from the given certain surfaces. Examples of head groups for SAMs that can form on metal surfaces include thiolates, metal-coordinating ligands, phosphines, amine groups, any suitable hydro-carbon SAM material, or any suitable combination thereof. Some specific examples of SAM will be described below herein.

A thickness of the deposition inhibitor 57 (to be sufficient as a blocking layer) can be a small as a single monolayer, in a range of 1 nm to 3 nm, and can be typically about 1 nm to 2 nm, depending on the specific molecules used in the deposition inhibitor and their packing density. Generally, the thickness of a deposition inhibitor, for example, can be determined by the length of the molecules that make up the monolayer and the orientation they adopt on the surface.

As noted above, some examples of head groups for SAMs that can form on metal surfaces include thiolates, metal-coordinating ligands, phosphines, amine groups, any suitable hydro-carbon SAM, or any suitable combination thereof. Next, some more specific examples of SAMs will be described.

Some example thiolates that can be suitable for chemisorption of the thiol (—SH) group onto metal atoms, interaction with metal atoms, and/or relatively stronger bonding with metal atoms relative to dielectric materials, for potential use in some embodiments, can include: alkanethiols (e.g., octanethiol; dodecanethiol) (e.g., for copper and cobalt); dithiol compounds (e.g., 1,8-octanedithiol (ODT); 1,2-ethanedithiol (EDT)) (e.g., for ruthenium); phosphonothiols, (e.g., hexanethiolphosphonic acid (HPTA)) (these molecules can contain both thiol and phosphonic acid groups, which can facilitate relatively stronger bonding and enable effective chemisorption onto metal surfaces) (e.g., for molybdenum and tungsten); or any suitable combination thereof.

Some example metal-coordinating ligands that can be suitable for interaction with metal atoms and/or relatively stronger bonding with metal atoms relative to dielectric materials, for potential use in some embodiments, can include: 1,10-phenanthroline (e.g., bidentate ligand) (e.g., for copper); 2,2′-bipyridine (e.g., bidentate ligand) (e.g., for cobalt); tris(2,2′-bipyridine) ruthenium (II) (Ru (bpy) 3\hat{ }2+) (e.g., bipyridine ligand) (e.g., for ruthenium); dimethylglyoxime (e.g., for molybdenum); tungsten hexacarbonyl (W(CO)₆) (e.g., six carbonyl (CO) ligands coordinated to a tungsten atom) (e.g., for tungsten); or any suitable combination thereof.

Some example phosphines (e.g., phosphine ligands) that can be suitable for interaction with metal atoms and/or relatively stronger bonding with metal atoms relative to dielectric materials, for potential use in some embodiments, can include: triphenylphosphine (PPh3) (e.g., for copper); tris(2-diphenylphosphinoethyl) amine (PNP) (e.g., for cobalt); tris(2-diphenylphosphinoethyl)phosphine (TPP) (e.g., for ruthenium); diphenylphosphinoethane (dppe) (e.g., bidentate phosphine ligand) (e.g., for molybdenum); and tris (tert-butyl) phosphine (tBu3P) (e.g., for tungsten); or any suitable combination thereof.

Some example amine groups (e.g., amine-containing ligands) that can be suitable for interaction with metal atoms and/or relatively stronger bonding with metal atoms relative to dielectric materials, for potential use in some embodiments, can include: diethylenetriamine (DETA) (e.g., polyamine ligand) (e.g., for copper); 1,4,8,11-tetraazacyclotetradecane (cyclam) (e.g., macrocyclic polyamine ligand) (e.g., for cobalt); 2,2′-Bipyridine (bipy) (e.g., for ruthenium); triethylenetetramine (TETA) (e.g., polyamine ligand) (e.g., for molybdenum); N,N-Dimethylethylenediamine (DMEDA) (e.g., diamine ligand) (e.g., for tungsten); or any suitable combination thereof.

Referring to FIG. 2B, a conductive liner 60 can be selectively deposited on the second intermediate structure 12 of FIG. 2A, to form a third intermediate structure 13 of FIG. 2B. In some embodiments, the conductive liner 60 can be selectively and conformally deposited directly on a first-dielectric-layer top surface 55 of the first dielectric layer 50 and directly on sidewalls of the via hole 40 (e.g., ALD and/or CVD and/or PECVD). In some embodiments, a line liner portion of the conductive liner 60 can be selectively and conformally deposited directly on a first-dielectric-layer top surface 55 of the first dielectric layer 50 and a via sidewall liner portion of the conductive liner 60 can be selectively and conformally deposited directly on a sidewall of the via hole 40. The deposition inhibitor 57 can block a formation of the conductive liner 60 on the underlying conductive structure 30.

Referring to FIG. 2C, the deposition inhibitor 57 can be removed to expose the underlying conductive structure 30 at the bottom of the via hole 40, to form a fourth intermediate structure 14. The deposition inhibitor 57 can be selectively removed without removing the conductive liner 60.

Referring to FIG. 2D, a conductive material for an interconnect structure 70 can be formed directly on the conductive liner 60 and directly on a top surface of the underlying conductive structure 30 (at the bottom of the via hole 40). The conductive material for the interconnect structure 70 can be ruthenium. In a same way as described above regarding FIG. 1C, for example, the via hole 40 can be overfilled with ruthenium such that a first thickness 73 of the ruthenium is formed on a conductive-liner top surface 65 of the fourth intermediate structure 14 of FIG. 2C, to form a fifth intermediate structure 15 of FIG. 2D.

Still referring to FIG. 2D, an interconnect structure 70 can have a via plug portion 71 at a first interconnect level M1 in the via hole 40 and directly on the underlying conductive structure 30, and a line portion 72 at a second interconnect level M2 extending directly on a top surface 65 of the conductive liner 60 (extending indirectly on the top surface 55 of the first dielectric layer 50). The via plug portion 71 can be contiguous and integral with the line portion 72 such that the line portion 72 is electrical connected with the underlying conductive structure 30 via the via plug portion 71. A via sidewall liner portion of the conductive liner 60 can be between the via plug portion 71 of the interconnect structure 70 and the sidewall of the via hole 40. A line liner portion of the conductive liner 60 can be between the line portion 72 of the interconnect structure 70 and a top surface 55 of the first dielectric layer 50.

By having the via plug portion 71 of the interconnect structure 70 formed directly on the underlying conductive structure 30, a contact resistance between the interconnect structure 70 and the underlying conductive structure 30 can be reduced compared to some embodiments having the conductive liner or some other liner/layer therebetween, for example. In some embodiments, a top surface of the underlying conductive structure 30 can be cleaned and/or submitted to a pretreatment process (if not already clean from the removal of deposition inhibitor 57) (e.g., to remove surface oxidation and/or to remove residue from the deposition inhibitor 57 and/or the deposition inhibitor removal process) prior to or immediately prior to depositing the ruthenium of the interconnect structure 70, to provide better electrical contact of the interconnect structure 70 with the underlying conductive structure 30.

Referring to FIGS. 2E to 2I, the intermediate structures can be formed and processed as described above relating to FIGS. 1D to 1H, respectively.

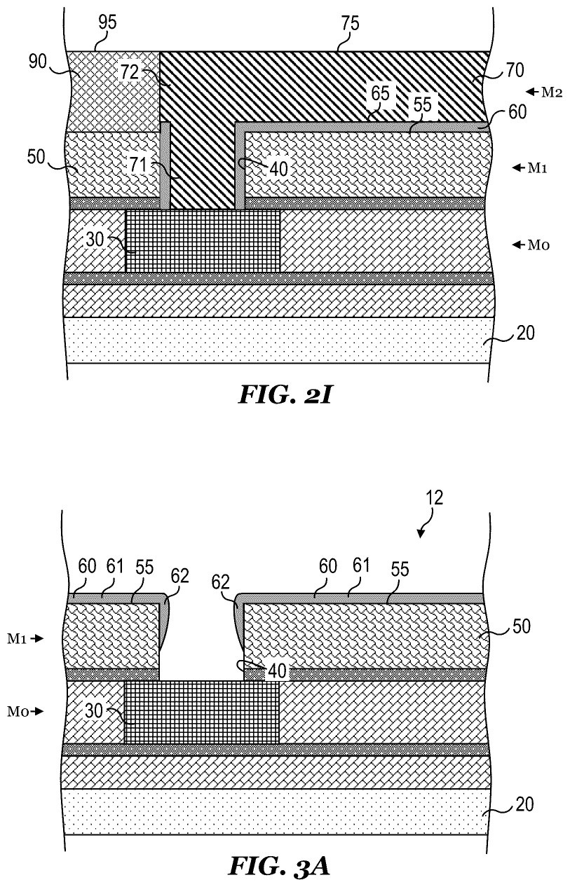

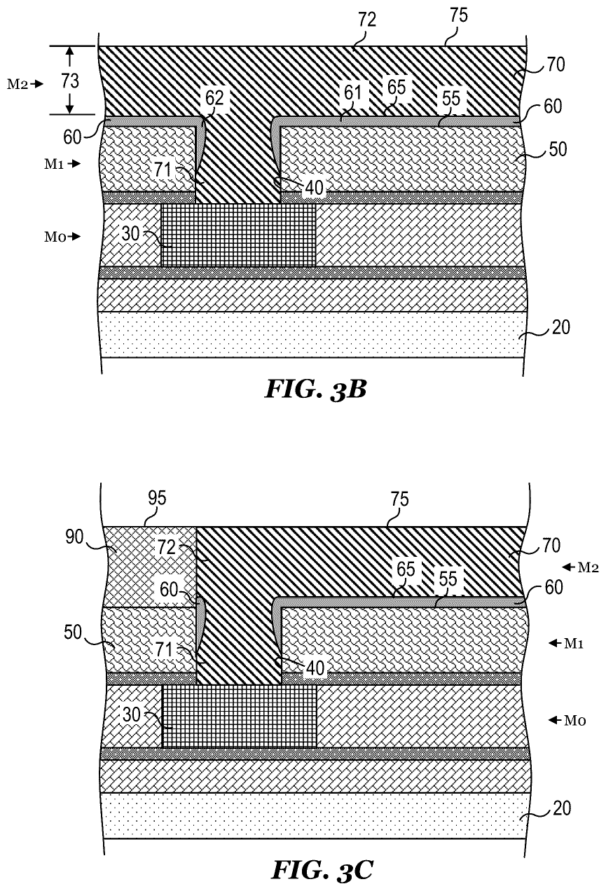

FIGS. 3A to 3C are cross-section views illustrating intermediate structures of a semiconductor device made using a method according to an embodiment of the present disclosure. Beginning with a first intermediate structure 11 of FIG. 1A, for example, a conductive liner 60 can be deposited on the first intermediate structure 11 to form a second intermediate structure 12 of FIG. 3A. The conductive liner 60 can be formed using a PEPVD and/or PVD process so that the conductive liner 60 forms on sidewalls of the via hole 40 (at least at an upper portion of the via hole 40) but not on a top surface of the underlying conductive structure 30. For example, a PVD can be used without using a bottom RF or relatively lower bottom RF for the lower electrode of the deposition chamber, so that the conductive material deposition is not deposited only in a vertical direction, and so that the conductive material (e.g., niobium) of the conductive liner 60 is less likely to form on the top surface of the underlying conductive structure 30 (e.g., not reaching the bottom of the via hole 40), while still depositing on an upper portion of the via hole 40 and on a top surface 55 of the first dielectric layer 50. For example, a PEPVD can be used with high pressure inert gas and low/no bias on a lower electrode of the plasma chamber so that the conductive material (e.g., niobium) of the conductive liner 60 is less likely to form on the top surface of the underlying conductive structure 30 (e.g., not reaching the bottom of the via hole 40), while still depositing on an upper portion of the via hole 40 and on a top surface 55 of the first dielectric layer 50. For example, an angled PVD (e.g., 45 degrees) can be used so that the conductive material (e.g., niobium) of the conductive liner 60 is less likely to form on the top surface of the underlying conductive structure 30 (e.g., not reaching the bottom of the via hole 40), while still depositing on an upper portion of the via hole 40 and on a top surface 55 of the first dielectric layer 50.

Still referring to FIG. 3A, in some embodiments, the forming of the conductive liner 60 can include depositing the conductive liner 60 over the first intermediate structure 11 using a physical vapor deposition process to form a second intermediate structure 12, such that a line liner portion 61 of the conductive liner 60 is formed directly on a first-dielectric-layer top surface 55 of the first dielectric layer 50 and a via sidewall liner portion 62 is formed directly on sidewalls of the via hole 40, where a thickness of the via sidewall liner portion 62 is greater at a via top portion of the via hole 40 than a via bottom portion of the via hole 40, and where at least part of the underlying conductive structure 30 remains exposed at a bottom of the via hole 40.

In some embodiments, portions of the conductive liner 60 may be on part of the top surface of the underlying conductive structure 30 while a remaining part of the top surface of the underlying conductive structure 30 remains exposed at a bottom of the via hole 40.

Referring to FIG. 3B, a conductive material for an interconnect structure 70 can be formed directly on the conductive liner 60 and directly on a top surface of the underlying conductive structure 30 (at the bottom of the via hole 40). The conductive material for the interconnect structure 70 can be ruthenium. In a same way as described above regarding FIG. 2D, for example, the via hole 40 can be overfilled with ruthenium such that a first thickness 73 of the ruthenium is formed on a conductive-liner top surface 65.

Still referring to FIG. 3B, an interconnect structure 70 can have a via plug portion 71 at a first interconnect level M1 in the via hole 40 and directly on the underlying conductive structure 30, and a line portion 72 at a second interconnect level M2 extending directly on a top surface 65 of the conductive liner 60 (extending indirectly on the top surface 55 of the first dielectric layer 50). The via plug portion 71 can be contiguous and integral with the line portion 72 such that the line portion 72 is electrical connected with the underlying conductive structure 30 via the via plug portion 71. A via sidewall liner portion 62 of the conductive liner 60 can be between the via plug portion 71 of the interconnect structure 70 and the sidewall of the via hole 40. A line liner portion 61 of the conductive liner 60 can be between the line portion 72 of the interconnect structure 70 and a top surface 55 of the first dielectric layer 50.

By having the via plug portion 71 of the interconnect structure 70 formed directly on the underlying conductive structure 30, a contact resistance between the interconnect structure 70 and the underlying conductive structure 30 can be reduced compared to some embodiments having the conductive liner or some other liner/layer therebetween, for example.

Referring to FIG. 3C, intermediate structures can be formed and processed between FIGS. 3B and 3C, as described above relating to FIGS. 2E to 2I, for example, to form the intermediate structure of FIG. 3C.

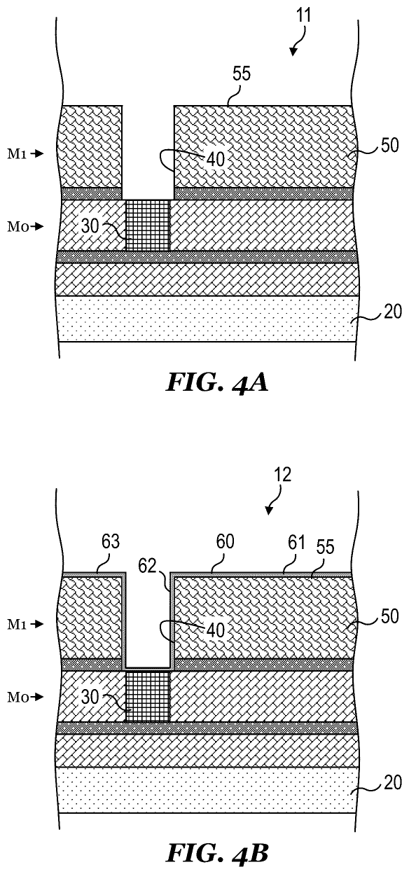

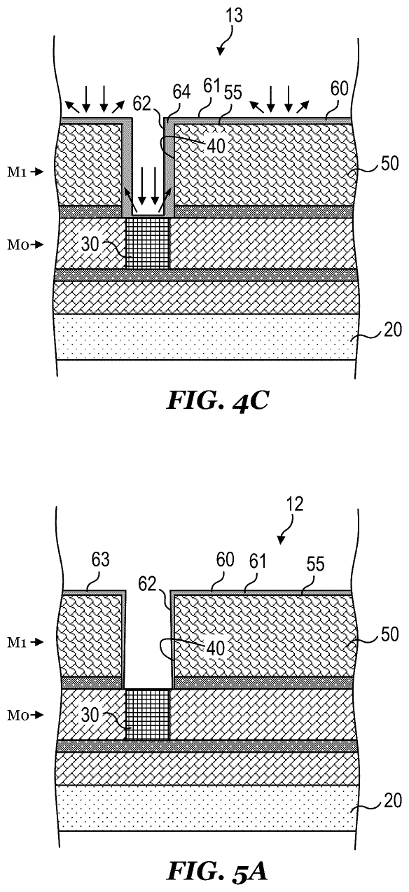

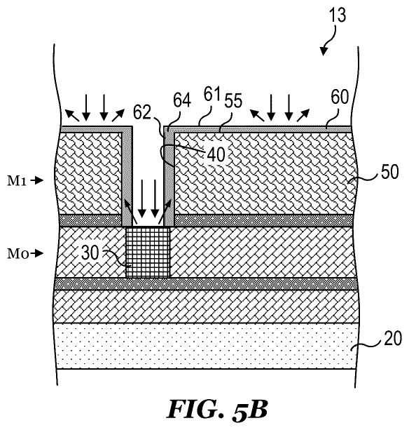

FIGS. 4A to 4C are cross-section views illustrating intermediate structures of a semiconductor device made using a method according to an embodiment of the present disclosure. FIGS. 5A to 5B are cross-section views illustrating intermediate structures of a semiconductor device made using a method according to an embodiment of the present disclosure. Referring to FIG. 4A, the description of FIG. 1A can apply also for FIG. 4A, for example.

Referring to FIGS. 4B to 4C and 5A to 5B, a conductive liner 60 can be formed with a first conductive-liner-deposition stage and a second conductive-liner-deposition stage, to form a second intermediate structure 12 and a third intermediate structure 13, respectively. The first conductive-liner-deposition stage can include depositing a first conductive-liner portion 63 on the first intermediate structure 11 (see FIG. 4A) such that a first-via-sidewall-liner portion of the via sidewall liner portion 62 has a first sidewall-portion thickness on the sidewall of the via hole 40, to form a second intermediate structure 12, as illustrated by examples in FIGS. 4B and 5A. As illustrated in FIG. 5A, a via sidewall liner portion 62 of the conductive liner can be thicker at an upper portion of the via hole 40 than at a lower portion of the via hole 40.

The second conductive-liner-deposition stage can include sputtering the first conductive-liner portion 63 with an inert gas using a high bias to remove via-bottom portions of the first conductive-liner portion 63 at a bottom of the via hole 40 and depositing a second conductive-liner portion 64 on the first-via-sidewall-liner portion of the via sidewall liner portion 62 such that the via sidewall liner portion 62 has a second sidewall-portion thickness on the sidewall of the via hole 40, to form a third intermediate structure 13 as illustrated by examples in FIGS. 4C and 5B, where the second sidewall-portion thickness is greater than the first sidewall-portion thickness. Material of first conductive-liner portion 63 at the bottom of the via hole 40 can be removed and sputtered onto the via sidewall liner portion 62 on the sidewalls of the via hole 40, thereby forming the second conductive-liner portion 64 and thereby increasing the thickness at the sidewalls of the via hole 40.

The second conductive-liner-deposition stage can include depositing material for the conductive liner 60 (e.g., niobium) and sputtering of the first conductive-liner portion 63 to at least partially expose the underlying conductive structure 30 at the bottom of the via hole 40, such that the line liner portion 61 remains on the first-dielectric-layer top surface 55 of the first dielectric layer 50, to form a third intermediate structure 13 as illustrated by examples in FIGS. 4C and 5B.

In an embodiment of the present disclosure shown in FIGS. 4B and 4C, the conductive liner 60 can remain on the top surface of the underlying conductive structure 30, so that the underlying conductive structure 30 is covered in the third intermediate structure 13, for example. In an embodiment of the present disclosure shown in FIGS. 5A and 5B, the conductive liner 60 can be removed from part of or all of the top surface of the underlying conductive structure 30, so that at least part of the underlying conductive structure 30 is exposed in the third intermediate structure 13, for example.

After forming the third intermediate structure 13 of FIG. 4C, additional intermediate structures can be formed as described above regarding FIGS. 1C to 1H, for example, to form an interconnect structure 70 in accordance with an embodiment of the present disclosure. After forming the third intermediate structure 13 of FIG. 5B, additional intermediate structures can be formed as described above regarding FIGS. 2D to 2I, for example, to form an interconnect structure 70 in accordance with an embodiment of the present disclosure.

In some embodiments, the intermediate structure 12 of FIG. 4B or 5A can be sufficient, without a need for a second deposition stage. Accordingly, in some embodiments, after forming the second intermediate structure 12 of FIG. 4B, additional intermediate structures can be formed as described above regarding FIGS. 1C to 1H, for example, to form an interconnect structure 70. Accordingly, in some embodiments, after forming the second intermediate structure 12 of FIG. 5A, additional intermediate structures can be formed as described above regarding FIGS. 2D to 2I, for example, to form an interconnect structure 70.

In some embodiments, a very thin layer of niobium with a thickness as thin as 1.2A or 1.8A in a via hole 40 can be formed using remote plasma and/or direct plasma deposition, which can be sufficient thickness to provide functions of an adhesion layer (e.g., for improving adhesion of a ruthenium interconnect structure to a low-k dielectric material) and as an etch stop layer to protect a low-k dielectric material of the first dielectric layer 50 (e.g., during an oxide-based etching of ruthenium in a subtractive semi-damascene process), for example.

Research and development have shown that depositing ruthenium directly on cobalt, copper, or cobalt-copper combinations can lead to intermixing of the ruthenium and formation of unwanted voids at the contract interface. Tests and experiments have shown that with a barrier layer of niobium with a thickness in a range of 1 nm to 10 nm between a top surface of an underlying conductive structure 30 that is cobalt, copper, or cobalt-copper combinations, and an interconnect structure 70 made from ruthenium, the niobium of the conductive liner 60 can perform well to prevent, hinder, or significantly reduce intermixing of the ruthenium with cobalt, copper, or cobalt-copper combinations, for example. Thus, an embodiment of the present disclosure, such as those described regarding FIGS. 1A to 1H, and/or FIGS. 4A to 4C, can be used where a top surface of the underlying conductive structure is cobalt, copper, or cobalt-copper combinations. Accordingly, in some embodiments, such as those described regarding FIGS. 1A to 1H, and/or FIGS. 4A to 4C, the conductive liner 60 can be niobium for an interconnect structure 70 made of ruthenium, where a top surface of the underlying conductive structure is cobalt, copper, or cobalt-copper combinations.

In some embodiments, an underlying conductive structure 30 can be ruthenium, and/or a top surface of an underlying conductive structure 30 can be ruthenium, and for such examples, an embodiment of the present disclosure, such as those described regarding FIGS. 2A to 2I, FIGS. 3A to 3C, and/or FIGS. 5A to 5B, can be used. For example, an interconnect structure 70 made of ruthenium can be formed directly on an underlying conductive structure 30 made of ruthenium.

In some embodiments, in a first deposition stage, an ionized PVD (iPVD) can be used without using a bottom RF or relatively lower bottom RF for the lower electrode of the deposition chamber (lower bias or no bias), so that the conductive material deposition is not directly deposited (perhaps with incomplete coverage) (e.g., with a thickness of 1 nm or less), and so that the conductive material (e.g., niobium) of the conductive liner 60 is less likely to form on the top surface of the underlying conductive structure 30 (e.g., not reaching the bottom of the via hole 40), while still depositing on an upper portion of the via hole 40 and on a top surface 55 of the first dielectric layer 50.

In some embodiments, an iPVD can be used with a plasma using only a top electrode (not energizing a bottom electrode) (e.g., without tracking) to allow tilted or non-directional PVD (e.g., not using directional collimated ion beams oriented vertically and/or not using a coulometer) (e.g., so that niobium sputtered from a target does not hit the intermediate structure in a directional manner, or at many different angles), which can result in no coverage or incomplete coverage or very minimal coverage of the conductive liner 60 on the bottom of the via hole 40 (e.g., on an exposed top surface of the underlying conductive structure 30), using a relatively higher pressure of the pre-cursor gases to reduce bouncing of the niobium upon hitting the intermediate structure (effectively making niobium more sticky upon hitting the intermediate structure, rather than having a bounce). The top or upper electrode of the chamber can be used for generating a plasma, but by leaving the bottom or lower electrode (e.g., at the wafer holder) of the chamber off (or at a very low level), the niobium leaving the target can be deposited at a variety of angles (rather than be collimated in a vertical direction mainly). Higher pressure and no bias (no energizing the lower electrode) during this deposition stage (e.g., with only a top/upper electrode energized) can assist in creating a variety of deposition angles and lower the speed or impact energy of the niobium particles hitting the surface of the intermediate structure. This can result in very little deposition of niobium at the bottom of the via hole 40.

In some embodiments, in a second deposition stage, using a highly directional beam (e.g., collimated ion beams directed vertically) (e.g., argon beam) (e.g., high bias using the upper and lower electrodes of the deposition chamber), to cause a sputtering to remove conductive material of the conductive liner 60 from the top surface of the underlying conductive structure 30 (at the bottom of the via hole 40), which can sputter (e.g., bombard with Ar ions in a highly-biased plasma) those removed particles onto sidewalls of the via hole 40 (making the thickness of the conductive liner 60 greater on the sidewalls than on the bottom of the via hole 40). Such a two-stage process can result in the conductive liner 60 being very thin or much thinner or incomplete coverage on the top surface of the underlying conductive structure 30 (at the bottom of the via hole 40), while having a relatively thicker and complete coverage for the conductive liner 60 on the sidewalls of the via hole 40 and on a top surface 55 of the first dielectric layer 50, for example. In some embodiments, it can be specified to has a niobium layer (of the conductive liner 60) at the bottom of the via hole 40 being as thin as possible, to minimize vertical resistance from the underlying conductive structure 30 into the ruthenium (of the interconnect structure 70) through the niobium (of the conductive liner 60). In some embodiments, a second deposition stage can include a flow of mostly argon gas along with some niobium pre-cursor gas, using a high bias as described above, such that the argon sputters while the niobium pre-cursor gas still deposits some niobium on the top surface of the intermediate structure 12 (e.g., top surface 55 of the first dielectric layer 50 and/or top surface of the line liner portion 61 of the conductive liner 60 from a first deposition stage). In some embodiments, a ratio of argon to niobium can be lower in a first deposition stage (with no bias, not directional, higher pressure) than in a second deposition stage (using high bias, vertical-oriented, directional) so that there is more argon sputtering than new niobium deposition at the bottom of the via hole 40. A relatively smaller amount of niobium flow rate in a second deposition stage can protect a top surface of the conductive liner 60 formed in a first deposition stage from being removed, which could be a no net deposition on a top surface (e.g., deposition rate is about the same as the sputtering etch rate) for a horizontal top surface of the conductive liner 60 formed in a first deposition stage). Controlling and tuning the argon to niobium ratio can be used to control the rate of sputter etching versus niobium deposition.

In some embodiments, a top layer of the conductive liner 60 on a top surface 55 of the first dielectric layer 50 can be about 8 nm thick after a first deposition stage and then about 6 nm thick after a second deposition stage (reduced due to argon sputtering). In some embodiments, the first deposition stage and the second deposition stage can be performed in a same chamber without removing the wafer, by simply changing the deposition parameters.

In some embodiments, where a top surface of the underlying conductive structure 30 includes copper, cobalt, or copper-cobalt combination, it can be better to leave some amount of the conductive liner 60 at the bottom of the via hole 40 to cover the underlying conductive structure 30 (e.g., at least a minimal thickness of 1.2A or 1.8A). In some embodiments, a second deposition stage with inert gas sputtering effect (especially for the bottom of the via hole 40) (e.g., argon as discussed above) can be used where there is less or no concern about sputtering materials of the underlying conductive structure 30, such as ruthenium, molybdenum, niobium, tungsten, tantalum, aluminum, or some combination thereof (e.g., not copper), onto the sidewalls of the via hole 40, especially if the bottom of the via hole 40 becomes partially or fully uncovered by the conductive liner 60 (e.g., because copper should not be directly contacting low-k dielectric), for example.

In some embodiments, a first deposition stage and a second deposition stage for forming a conductive liner 60 made of niobium can have the deposition parameters of Table 1.

TABLE 1

| Parameters | First deposition stage | | Second deposition stage | |
|---|---|---|---|---|
| Pressure | 50 to 100 | mT | 0.5 to 5.0 | mT |
| Ar gas flow | 20 to 100 | sccm | 5 to 50 | mT |
| Temperature | −30 to 10 | C | −30 to 10 | C |
| ICP power | 300 to 1000 | W | 1000 to 2000 | W |
| DC power | 400 to 1200 | W | 0 to 1200 | W |
| Stage RF bias | 0 | W | 750 to 950 | W |

Using an embodiment of the present disclosure, a conductive liner 60 of niobium can greatly improve an adhesion of an interconnect structure 70 of ruthenium relative to low-k dielectric material(s) of a first dielectric layer 50, such as during a CMP operation, for example.

Using an embodiment of the present disclosure, a conductive liner 60 of niobium can act as an etch stop layer and protect an underlying portion of low-k material(s) of a first dielectric layer 50 during etching of an interconnect structure 70 of ruthenium during a subtractive semi-damascene process flow.

Using an embodiment of the present disclosure, a conductive liner 60 of niobium can act as a barrier layer between an interconnect structure 70 of ruthenium and an underlying conductive structure 30 of copper, cobalt, or copper-cobalt combination.

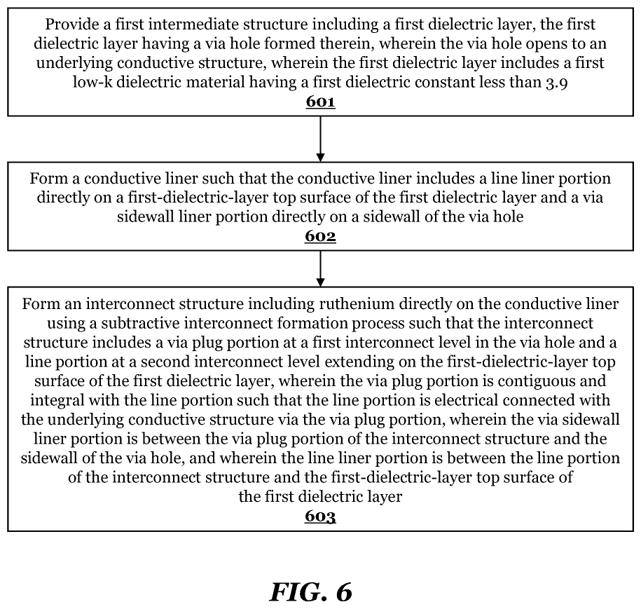

FIG. 6 illustrates a flow chart for a method of making a semiconductor device incorporating a conductive liner for an interconnect structure, in accordance with an embodiment of the present disclosure. In an embodiment, a method for making a semiconductor device includes providing a first intermediate structure including a first dielectric layer, the first dielectric layer having a via hole formed therein, wherein the via hole opens to an underlying conductive structure, wherein the first dielectric layer includes a first low-k dielectric material having a first dielectric constant less than 3.9 (box 601).

In an embodiment, a method for making a semiconductor device includes forming a conductive liner such that the conductive liner includes a line liner portion directly on a first-dielectric-layer top surface of the first dielectric layer and a via sidewall liner portion directly on a sidewall of the via hole (box 602).

In an embodiment, a method for making a semiconductor device includes forming an interconnect structure including ruthenium directly on the conductive liner using a subtractive interconnect formation process such that the interconnect structure includes a via plug portion at a first interconnect level in the via hole and a line portion at a second interconnect level extending on the first-dielectric-layer top surface of the first dielectric layer, wherein the via plug portion is contiguous and integral with the line portion such that the line portion is electrical connected with the underlying conductive structure via the via plug portion, wherein the via sidewall liner portion is between the via plug portion of the interconnect structure and the sidewall of the via hole, and wherein the line liner portion is between the line portion of the interconnect structure and the first-dielectric-layer top surface of the first dielectric layer (box 603).

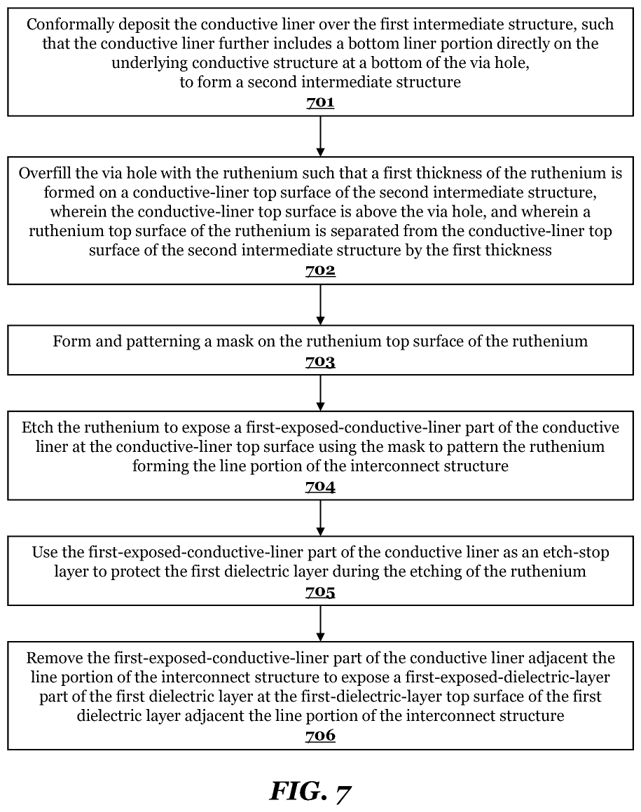

FIG. 7 illustrates a flow chart for a method of making a semiconductor device incorporating a conductive liner for an interconnect structure, in accordance with an embodiment of the present disclosure. The flow chart of FIG. 7 can be a continuation of the flow chart of FIG. 6. In an embodiment, forming the conductive liner includes conformally depositing the conductive liner over the first intermediate structure, such that the conductive liner further includes a bottom liner portion directly on the underlying conductive structure at a bottom of the via hole to form a second intermediate structure (box 701).

In an embodiment, a method for making a semiconductor device includes overfilling the via hole with the ruthenium such that a first thickness of the ruthenium is formed on a conductive-liner top surface of the second intermediate structure, wherein the conductive-liner top surface is above the via hole, and wherein a ruthenium top surface of the ruthenium is separated from the conductive-liner top surface of the second intermediate structure by the first thickness (box 702).

In an embodiment, a method for making a semiconductor device includes forming and patterning a mask on the ruthenium top surface of the ruthenium (box 703).

In an embodiment, a method for making a semiconductor device includes etching the ruthenium to expose a first-exposed-conductive-liner part of the conductive liner at the conductive-liner top surface using the mask to pattern the ruthenium forming the line portion of the interconnect structure (box 704).

In an embodiment, a method for making a semiconductor device includes using the first-exposed-conductive-liner part of the conductive liner as an etch-stop layer to protect the first dielectric layer during the etching of the ruthenium (box 705).

In an embodiment, a method for making a semiconductor device includes removing the first-exposed-conductive-liner part of the conductive liner adjacent the line portion of the interconnect structure to expose a first-exposed-dielectric-layer part of the first dielectric layer at the first-dielectric-layer top surface of the first dielectric layer adjacent the line portion of the interconnect structure (box 706).

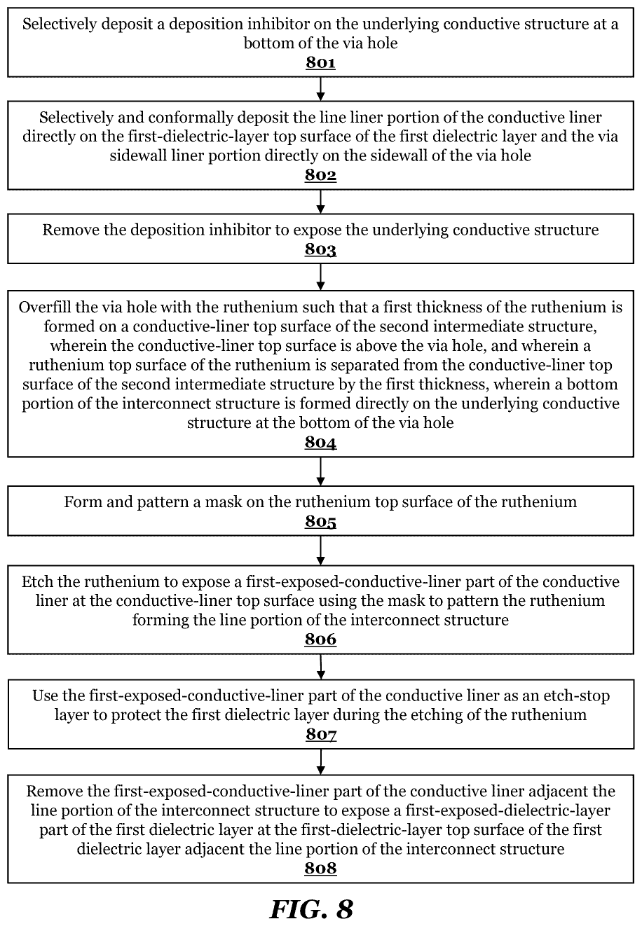

FIG. 8 illustrates a flow chart for a method of making a semiconductor device incorporating a conductive liner for an interconnect structure, in accordance with an embodiment of the present disclosure. The flow chart of FIG. 8 can be a continuation of the flow chart of FIG. 6. In an embodiment, forming the conductive liner includes selectively depositing a deposition inhibitor on the underlying conductive structure at a bottom of the via hole (box 801).

In an embodiment, forming the conductive liner includes selectively and conformally depositing the line liner portion of the conductive liner directly on the first-dielectric-layer top surface of the first dielectric layer and the via sidewall liner portion directly on the sidewall of the via hole (box 802).

In an embodiment, forming the conductive liner includes removing the deposition inhibitor to expose the underlying conductive structure (box 803).

In an embodiment, a method for making a semiconductor device includes overfilling the via hole with the ruthenium such that a first thickness of the ruthenium is formed on a conductive-liner top surface of the second intermediate structure, wherein the conductive-liner top surface is above the via hole, and wherein a ruthenium top surface of the ruthenium is separated from the conductive-liner top surface of the second intermediate structure by the first thickness, wherein a bottom portion of the interconnect structure is formed directly on the underlying conductive structure at the bottom of the via hole (box 804).

In an embodiment, a method for making a semiconductor device includes forming and patterning a mask on the ruthenium top surface of the ruthenium (box 805).

In an embodiment, a method for making a semiconductor device includes etching the ruthenium to expose a first-exposed-conductive-liner part of the conductive liner at the conductive-liner top surface using the mask to pattern the ruthenium forming the line portion of the interconnect structure (box 806).

In an embodiment, a method for making a semiconductor device includes using the first-exposed-conductive-liner part of the conductive liner as an etch-stop layer to protect the first dielectric layer during the etching of the ruthenium (box 807).

In an embodiment, a method for making a semiconductor device includes removing the first-exposed-conductive-liner part of the conductive liner adjacent the line portion of the interconnect structure to expose a first-exposed-dielectric-layer part of the first dielectric layer at the first-dielectric-layer top surface of the first dielectric layer adjacent the line portion of the interconnect structure (box 808).

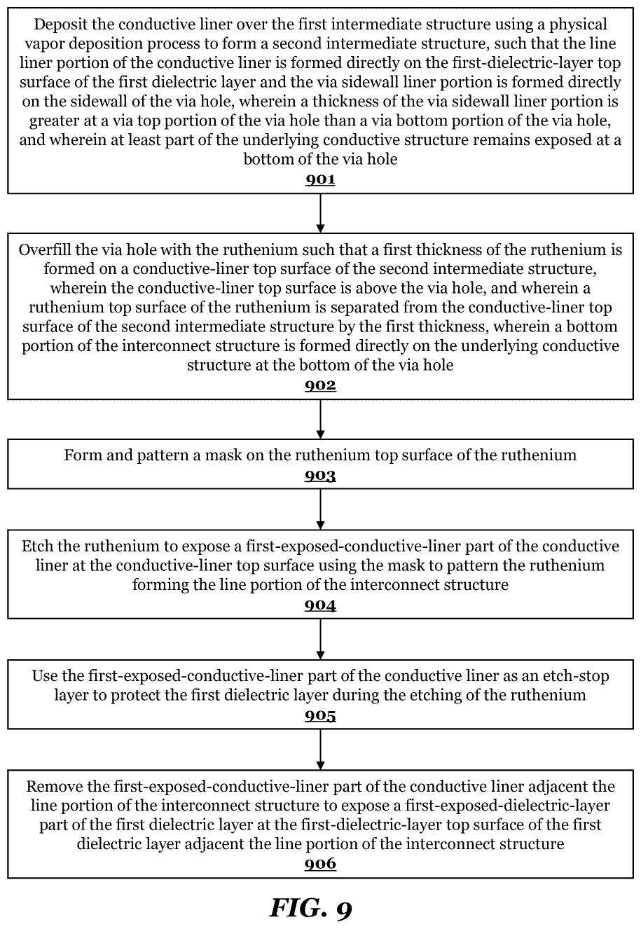

FIG. 9 illustrates a flow chart for a method of making a semiconductor device incorporating a conductive liner for an interconnect structure, in accordance with an embodiment of the present disclosure. The flow chart of FIG. 9 can be a continuation of the flow chart of FIG. 6. In an embodiment, forming the conductive liner includes depositing the conductive liner over the first intermediate structure using a physical vapor deposition process to form a second intermediate structure, such that the line liner portion of the conductive liner is formed directly on the first-dielectric-layer top surface of the first dielectric layer and the via sidewall liner portion is formed directly on the sidewall of the via hole, wherein a thickness of the via sidewall liner portion is greater at a via top portion of the via hole than a via bottom portion of the via hole, and wherein at least part of the underlying conductive structure remains exposed at a bottom of the via hole (box 901).

In an embodiment, a method for making a semiconductor device includes overfilling the via hole with the ruthenium such that a first thickness of the ruthenium is formed on a conductive-liner top surface of the second intermediate structure, wherein the conductive-liner top surface is above the via hole, and wherein a ruthenium top surface of the ruthenium is separated from the conductive-liner top surface of the second intermediate structure by the first thickness, wherein a bottom portion of the interconnect structure is formed directly on the underlying conductive structure at the bottom of the via hole (box 902).

In an embodiment, a method for making a semiconductor device includes forming and patterning a mask on the ruthenium top surface of the ruthenium (box 903).

In an embodiment, a method for making a semiconductor device includes etching the ruthenium to expose a first-exposed-conductive-liner part of the conductive liner at the conductive-liner top surface using the mask to pattern the ruthenium forming the line portion of the interconnect structure (box 904).

In an embodiment, a method for making a semiconductor device includes using the first-exposed-conductive-liner part of the conductive liner as an etch-stop layer to protect the first dielectric layer during the etching of the ruthenium (box 905).

In an embodiment, a method for making a semiconductor device includes removing the first-exposed-conductive-liner part of the conductive liner adjacent the line portion of the interconnect structure to expose a first-exposed-dielectric-layer part of the first dielectric layer at the first-dielectric-layer top surface of the first dielectric layer adjacent the line portion of the interconnect structure (box 906).

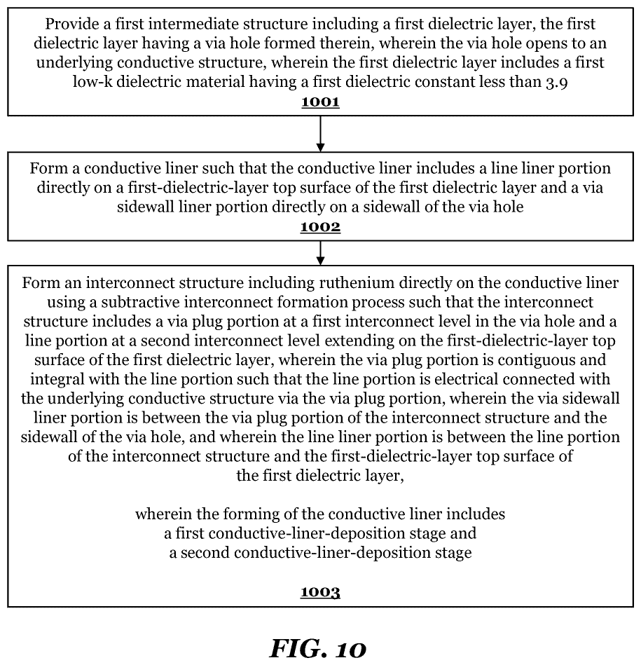

FIG. 10 illustrates a flow chart for a method of making a semiconductor device incorporating a conductive liner for an interconnect structure, in accordance with an embodiment of the present disclosure. In an embodiment, a method for making a semiconductor device includes providing a first intermediate structure including a first dielectric layer, the first dielectric layer having a via hole formed therein, wherein the via hole opens to an underlying conductive structure, wherein the first dielectric layer includes a first low-k dielectric material having a first dielectric constant less than 3.9 (box 1001).

In an embodiment, a method for making a semiconductor device includes forming a conductive liner such that the conductive liner includes a line liner portion directly on a first-dielectric-layer top surface of the first dielectric layer and a via sidewall liner portion directly on a sidewall of the via hole (box 1002).

In an embodiment, a method for making a semiconductor device includes forming an interconnect structure including ruthenium directly on the conductive liner using a subtractive interconnect formation process such that the interconnect structure includes a via plug portion at a first interconnect level in the via hole and a line portion at a second interconnect level extending on the first-dielectric-layer top surface of the first dielectric layer, wherein the via plug portion is contiguous and integral with the line portion such that the line portion is electrical connected with the underlying conductive structure via the via plug portion, wherein the via sidewall liner portion is between the via plug portion of the interconnect structure and the sidewall of the via hole, and wherein the line liner portion is between the line portion of the interconnect structure and the first-dielectric-layer top surface of the first dielectric layer (box 1003).

In an embodiment, the forming of the conductive liner includes a first conductive-liner-deposition stage and a second conductive-liner-deposition stage (box 1003).

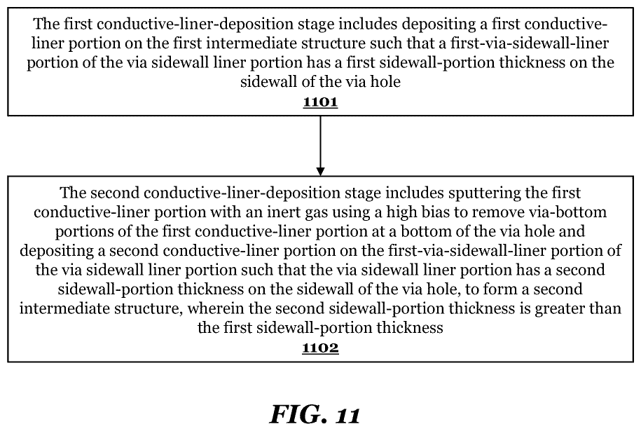

FIG. 11 illustrates a flow chart for a method of making a semiconductor device incorporating a conductive liner for an interconnect structure, in accordance with an embodiment of the present disclosure. The flow chart of FIG. 11 can be a continuation of the flow chart of FIG. 10. In an embodiment, the first conductive-liner-deposition stage includes depositing a first conductive-liner portion on the first intermediate structure such that a first-via-sidewall-liner portion of the via sidewall liner portion has a first sidewall-portion thickness on the sidewall of the via hole (box 1101).

In an embodiment, the second conductive-liner-deposition stage includes sputtering the first conductive-liner portion with an inert gas using a high bias to remove via-bottom portions of the first conductive-liner portion at a bottom of the via hole and depositing a second conductive-liner portion on the first-via-sidewall-liner portion of the via sidewall liner portion such that the via sidewall liner portion has a second sidewall-portion thickness on the sidewall of the via hole, to form a second intermediate structure, wherein the second sidewall-portion thickness is greater than the first sidewall-portion thickness (box 1102).

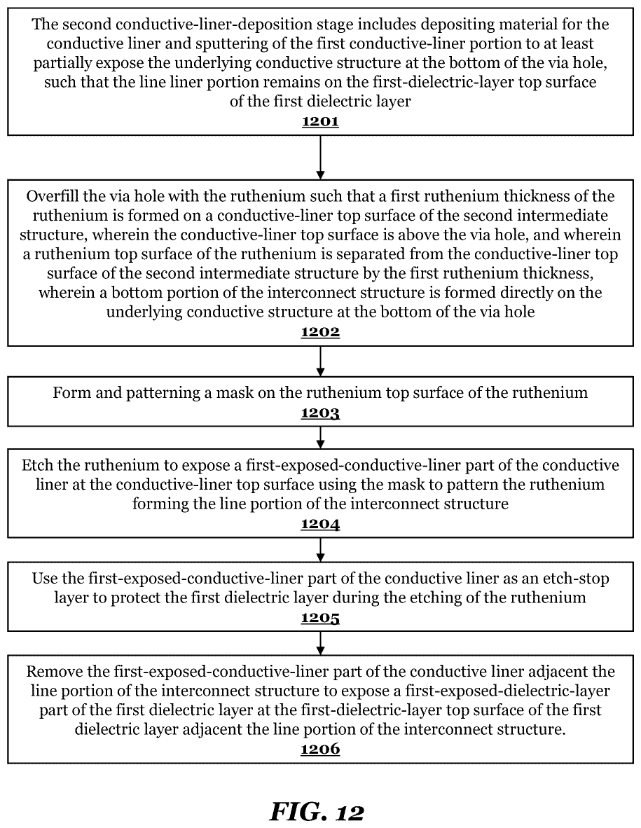

FIG. 12 illustrates a flow chart for a method of making a semiconductor device incorporating a conductive liner for an interconnect structure, in accordance with an embodiment of the present disclosure. The flow chart of FIG. 12 can be a continuation of the flow charts of FIGS. 10 and 11. In an embodiment, the second conductive-liner-deposition stage includes depositing material for the conductive liner and sputtering of the first conductive-liner portion to at least partially expose the underlying conductive structure at the bottom of the via hole, such that the line liner portion remains on the first-dielectric-layer top surface of the first dielectric layer (box 1201).

In an embodiment, a method for making a semiconductor device includes overfilling the via hole with the ruthenium such that a first ruthenium thickness of the ruthenium is formed on a conductive-liner top surface of the second intermediate structure, wherein the conductive-liner top surface is above the via hole, and wherein a ruthenium top surface of the ruthenium is separated from the conductive-liner top surface of the second intermediate structure by the first ruthenium thickness, wherein a bottom portion of the interconnect structure is formed directly on the underlying conductive structure at the bottom of the via hole (box 1202).

In an embodiment, a method for making a semiconductor device includes forming and patterning a mask on the ruthenium top surface of the ruthenium (box 1203).

In an embodiment, a method for making a semiconductor device includes etching the ruthenium to expose a first-exposed-conductive-liner part of the conductive liner at the conductive-liner top surface using the mask to pattern the ruthenium forming the line portion of the interconnect structure (box 1204).

In an embodiment, a method for making a semiconductor device includes using the first-exposed-conductive-liner part of the conductive liner as an etch-stop layer to protect the first dielectric layer during the etching of the ruthenium (box 1205).

In an embodiment, a method for making a semiconductor device includes removing the first-exposed-conductive-liner part of the conductive liner adjacent the line portion of the interconnect structure to expose a first-exposed-dielectric-layer part of the first dielectric layer at the first-dielectric-layer top surface of the first dielectric layer adjacent the line portion of the interconnect structure (box 1206).

The embodiments described in FIGS. 6-12 may be implemented as further described using any combination of FIGS. 1A-5B.

While illustrative and example embodiments have been described with reference to illustrative drawings, this description is not intended to be construed in a limiting sense. Various modifications and combinations of the illustrative and example embodiments, as well as other embodiments, can be apparent to persons skilled in the pertinent art upon referencing the present disclosure. It is therefore intended that the appended claims encompass any and all of such modifications, equivalents, or embodiments.

What is claimed is:

1. A method for making a semiconductor device, the method comprising:
providing a first intermediate structure comprising a first dielectric layer, the first dielectric layer having a via hole formed therein, wherein the via hole opens to an underlying conductive structure, wherein the first dielectric layer comprises a first low-k dielectric material having a first dielectric constant less than 3.9;
forming a conductive liner such that the conductive liner comprises a line liner portion directly on a first-dielectric-layer top surface of the first dielectric layer and a via sidewall liner portion directly on a sidewall of the via hole; and
forming an interconnect structure comprising ruthenium directly on the conductive liner using a subtractive interconnect formation process such that the interconnect structure comprises a via plug portion at a first interconnect level in the via hole and a line portion at a second interconnect level extending on the first-dielectric-layer top surface of the first dielectric layer, wherein the via plug portion is contiguous and integral with the line portion such that the line portion is electrical connected with the underlying conductive structure via the via plug portion, wherein the via sidewall liner portion is between the via plug portion of the interconnect structure and the sidewall of the via hole, and wherein the line liner portion is between the line portion of the interconnect structure and the first-dielectric-layer top surface of the first dielectric layer.

2. The method of claim 1, wherein the conductive liner comprises niobium.

3. The method of claim 1, wherein the forming of the conductive liner comprises conformally depositing the conductive liner over the first intermediate structure, such that the conductive liner further comprises a bottom liner portion directly on the underlying conductive structure at a bottom of the via hole, to form a second intermediate structure.

4. The method of claim 3, wherein the forming of the interconnect structure comprises:
overfilling the via hole with the ruthenium such that a first thickness of the ruthenium is formed on a conductive-liner top surface of the second intermediate structure, wherein the conductive-liner top surface is above the via hole, and wherein a ruthenium top surface of the ruthenium is separated from the conductive-liner top surface of the second intermediate structure by the first thickness;
forming and patterning a mask on the ruthenium top surface of the ruthenium;
etching the ruthenium to expose a first-exposed-conductive-liner part of the conductive liner at the conductive-liner top surface using the mask to pattern the ruthenium forming the line portion of the interconnect structure;
using the first-exposed-conductive-liner part of the conductive liner as an etch-stop layer to protect the first dielectric layer during the etching of the ruthenium; and
removing the first-exposed-conductive-liner part of the conductive liner adjacent the line portion of the interconnect structure to expose a first-exposed-dielectric-layer part of the first dielectric layer at the first-dielectric-layer top surface of the first dielectric layer adjacent the line portion of the interconnect structure.

5. The method of claim 4, wherein the etching of the ruthenium is performed with a first etch chemistry in a first etch chamber, and wherein the removing of the first-exposed-conductive-liner part of the conductive liner is performed with an etch of a second etch chemistry in the first etch chamber, wherein the first etch chemistry differs from the second etch chemistry, and wherein the first etch chemistry is selective to etch the ruthenium faster than the conductive liner.

6. The method of claim 4, further comprising:
removing the mask;
depositing a second dielectric layer on the first-exposed-dielectric-layer part of the first dielectric layer and on the line portion of the interconnect structure; and
planarizing a second-dielectric-layer top surface of the second dielectric layer and a line-portion top surface of the line portion.

7. The method of claim 6, wherein the removing of the mask is after the removing of the first-exposed-conductive-liner part of the conductive liner adjacent the line portion of the interconnect structure.

8. The method of claim 6, wherein the removing of the mask is before the removing of the first-exposed-conductive-liner part of the conductive liner adjacent the line portion of the interconnect structure.

9. The method of claim 1, wherein the forming of the conductive liner comprises:
selectively depositing a deposition inhibitor on the underlying conductive structure at a bottom of the via hole;
selectively and conformally depositing the line liner portion of the conductive liner directly on the first-dielectric-layer top surface of the first dielectric layer and the via sidewall liner portion directly on the sidewall of the via hole; and
removing the deposition inhibitor to expose the underlying conductive structure, to form a second intermediate structure.

10. The method of claim 9, wherein the forming of the interconnect structure comprises:
overfilling the via hole with the ruthenium such that a first thickness of the ruthenium is formed on a conductive-liner top surface of the second intermediate structure, wherein the conductive-liner top surface is above the via hole, and wherein a ruthenium top surface of the ruthenium is separated from the conductive-liner top surface of the second intermediate structure by the first thickness, wherein a bottom portion of the interconnect structure is formed directly on the underlying conductive structure at the bottom of the via hole;
forming and patterning a mask on the ruthenium top surface of the ruthenium;
etching the ruthenium to expose a first-exposed-conductive-liner part of the conductive liner at the conductive-liner top surface using the mask to pattern the ruthenium forming the line portion of the interconnect structure;
using the first-exposed-conductive-liner part of the conductive liner as an etch-stop layer to protect the first dielectric layer during the etching of the ruthenium; and
removing the first-exposed-conductive-liner part of the conductive liner adjacent the line portion of the interconnect structure to expose a first-exposed-dielectric-layer part of the first dielectric layer at the first-dielectric-layer top surface of the first dielectric layer adjacent the line portion of the interconnect structure.

11. The method of claim 10, wherein the etching of the ruthenium is performed with a first etch chemistry in a first etch chamber, and wherein the removing of the first-exposed-conductive-liner part of the conductive liner is performed with an etch of a second etch chemistry in the first etch chamber, wherein the first etch chemistry differs from the second etch chemistry, and wherein the first etch chemistry is selective to etch the ruthenium faster than the conductive liner.

12. The method of claim 10, further comprising:
removing the mask;
depositing a second dielectric layer on the first-exposed-dielectric-layer part of the first dielectric layer and on the line portion of the interconnect structure; and
planarizing a second-dielectric-layer top surface of the second dielectric layer and a line-portion top surface of the line portion.

13. The method of claim 12, wherein the removing of the mask is after the removing of the first-exposed-conductive-liner part of the conductive liner adjacent the line portion of the interconnect structure.

14. The method of claim 12, wherein the removing of the mask is before the removing of the first-exposed-conductive-liner part of the conductive liner adjacent the line portion of the interconnect structure.

15. The method of claim 1, wherein the forming of the conductive liner comprises depositing the conductive liner over the first intermediate structure using a physical vapor deposition process to form a second intermediate structure, such that the line liner portion of the conductive liner is formed directly on the first-dielectric-layer top surface of the first dielectric layer and the via sidewall liner portion is formed directly on the sidewall of the via hole, wherein a thickness of the via sidewall liner portion is greater at a via top portion of the via hole than a via bottom portion of the via hole, and wherein at least part of the underlying conductive structure remains exposed at a bottom of the via hole.

16. The method of claim 15, wherein the forming of the interconnect structure comprises:
overfilling the via hole with the ruthenium such that a first thickness of the ruthenium is formed on a conductive-liner top surface of the second intermediate structure, wherein the conductive-liner top surface is above the via hole, and wherein a ruthenium top surface of the ruthenium is separated from the conductive-liner top surface of the second intermediate structure by the first thickness, wherein a bottom portion of the interconnect structure is formed directly on the underlying conductive structure at the bottom of the via hole;
forming and patterning a mask on the ruthenium top surface of the ruthenium;
etching the ruthenium to expose a first-exposed-conductive-liner part of the conductive liner at the conductive-liner top surface using the mask to pattern the ruthenium forming the line portion of the interconnect structure;
using the first-exposed-conductive-liner part of the conductive liner as an etch-stop layer to protect the first dielectric layer during the etching of the ruthenium; and
removing the first-exposed-conductive-liner part of the conductive liner adjacent the line portion of the interconnect structure to expose a first-exposed-dielectric-layer part of the first dielectric layer at the first-dielectric-layer top surface of the first dielectric layer adjacent the line portion of the interconnect structure.

17. The method of claim 16, wherein the etching of the ruthenium is performed with a first etch chemistry in a first etch chamber, and wherein the removing of the first-exposed-conductive-liner part of the conductive liner is performed with an etch of a second etch chemistry in the first etch chamber, wherein the first etch chemistry differs from the second etch chemistry, and wherein the first etch chemistry is selective to etch the ruthenium faster than the conductive liner.

18. A method for making a semiconductor device, the method comprising:
providing a first intermediate structure comprising a first dielectric layer, the first dielectric layer having a via hole formed therein, wherein the via hole opens to an underlying conductive structure, wherein the first dielectric layer comprises a first low-k dielectric material having a first dielectric constant less than 3.9;
forming a conductive liner such that the conductive liner comprises a line liner portion directly on a first-dielectric-layer top surface of the first dielectric layer and a via sidewall liner portion directly on a sidewall of the via hole; and
forming an interconnect structure comprising ruthenium directly on the conductive liner using a subtractive interconnect formation process such that the interconnect structure comprises a via plug portion at a first interconnect level in the via hole and a line portion at a second interconnect level extending on the first-dielectric-layer top surface of the first dielectric layer, wherein the via plug portion is contiguous and integral with the line portion such that the line portion is electrical connected with the underlying conductive structure via the via plug portion, wherein the via sidewall liner portion is between the via plug portion of the interconnect structure and the sidewall of the via hole, and wherein the line liner portion is between the line portion of the interconnect structure and the first-dielectric-layer top surface of the first dielectric layer,
wherein the forming of the conductive liner comprises a first conductive-liner-deposition stage and a second conductive-liner-deposition stage,
wherein the first conductive-liner-deposition stage comprises depositing a first conductive-liner portion on the first intermediate structure such that a first-via-sidewall-liner portion of the via sidewall liner portion has a first sidewall-portion thickness on the sidewall of the via hole,
wherein the second conductive-liner-deposition stage comprises sputtering the first conductive-liner portion with an inert gas using a high bias to remove via-bottom portions of the first conductive-liner portion at a bottom of the via hole and depositing a second conductive-liner portion on the first-via-sidewall-liner portion of the via sidewall liner portion such that the via sidewall liner portion has a second sidewall-portion thickness on the sidewall of the via hole, to form a second intermediate structure, wherein the second sidewall-portion thickness is greater than the first sidewall-portion thickness.

19. The method of claim 18, wherein the second conductive-liner-deposition stage comprises depositing material for the conductive liner and sputtering of the first conductive-liner portion to at least partially expose the underlying conductive structure at the bottom of the via hole, such that the line liner portion remains on the first-dielectric-layer top surface of the first dielectric layer, and
wherein the forming of the interconnect structure comprises:
overfilling the via hole with the ruthenium such that a first ruthenium thickness of the ruthenium is formed on a conductive-liner top surface of the second intermediate structure, wherein the conductive-liner top surface is above the via hole, and wherein a ruthenium top surface of the ruthenium is separated from the conductive-liner top surface of the second intermediate structure by the first ruthenium thickness, wherein a bottom portion of the interconnect structure is formed directly on the underlying conductive structure at the bottom of the via hole;
forming and patterning a mask on the ruthenium top surface of the ruthenium;
etching the ruthenium to expose a first-exposed-conductive-liner part of the conductive liner at the conductive-liner top surface using the mask to pattern the ruthenium forming the line portion of the interconnect structure;
using the first-exposed-conductive-liner part of the conductive liner as an etch-stop layer to protect the first dielectric layer during the etching of the ruthenium; and
removing the first-exposed-conductive-liner part of the conductive liner adjacent the line portion of the interconnect structure to expose a first-exposed-dielectric-layer part of the first dielectric layer at the first-dielectric-layer top surface of the first dielectric layer adjacent the line portion of the interconnect structure.

20. The method of claim 18, wherein the conductive liner comprises niobium.

21. A semiconductor device comprising:
a first dielectric layer having a via hole therein, wherein the first dielectric layer comprises a first low-k dielectric material having a first dielectric constant less than 3.9;
an interconnect structure comprising a via plug portion at a first interconnect level in the via hole and a line portion at a second interconnect level extending on a top surface of the first dielectric layer, wherein the via plug portion is contiguous and integral with the line portion, and wherein the interconnect structure comprises ruthenium; and
a liner comprising a via sidewall liner portion and a line liner portion, wherein the via sidewall liner portion is directly on the first dielectric layer at a sidewall of the via hole between the via plug portion of the interconnect structure and the sidewall of the via hole, wherein the line liner portion is directly on the top surface of the first dielectric layer between the line portion of the interconnect structure and the top surface of the first dielectric layer, wherein at least part of the interconnect structure is directly on the liner, and wherein the liner comprises niobium.

22. The semiconductor device of claim 21, further comprising an underlying conductive structure below the via plug portion of the interconnect structure; and
wherein the liner further comprises a bottom liner portion between the via plug portion of the interconnect structure and the underlying conductive structure.
